(19) United States
(12) Patent Application Publication
(10) Pub. No.: US 2025/0056828 A1
(43) Pub. Date: Feb. 13, 2025

(54) VERTICALLY-ARRANGED GATE ALL AROUND TRANSISTORS HAVING UNIFORM CELL CONTACT LIGHTLY-DOPED DRAIN REGIONS

(71) Applicant: Micron Technology, Inc., Boise, ID (US)

(72) Inventors: Si-Woo LEE, Boise, ID (US); Yuichi YOKOYAMA, Boise, ID (US); Scott E. SILLS, Boise, ID (US); Gautham MUTHUSAMY, Boise, ID (US); David HWANG, Boise, ID (US); Yoshitaka NAKAMURA, Boise, ID (US); Pavani Vamsi Krishna NITTALA, Meridian, ID (US); Yuanzhi MA, Meridian, ID (US); Glen H. WALTERS, Woodlawn, MD (US); Haitao LIU, Boise, ID (US); Kamal M. KARDA, Boise, ID (US)

(21) Appl. No.: 18/783,224

(22) Filed: Jul. 24, 2024

Related U.S. Application Data
(60) Provisional application No. 63/518,161, filed on Aug. 8, 2023.

(51) Int. Cl. H01L 29/78; H01L 21/223; H01L 21/8234; H01L 29/06; H01L 29/423; H01L 29/775; H01L 29/786; H10B 12/00

(52) U.S. Cl. CPC H01L 29/7835; H01L 21/823418; H01L 28/86; H01L 28/90; H10B 12/01; H10B 12/318; H01L 21/223; H01L 29/0673; H01L 29/42392; H01L 29/775; H01L 29/78696

(57) ABSTRACT

Some implementations herein provide for a memory device and methods of formation. The memory device includes a plurality of storage cells arranged vertically and a plurality of corresponding gate all around transistors. Methods of forming the memory device include using a single trench to remove a liner material and form recesses that define cell contact lightly-doped drain regions of the gate all around transistors. Using the single trench to remove the liner material and form the recesses that define the cell contact lightly-doped drain region widths causes the cell contact lightly-doped drain regions to be formed having substantially similar widths.

### CROSS REFERENCE TO RELATED APPLICATION

This Patent Application claims priority to U.S. Provisional Patent Application No. 63/518, 161, filed on Aug. 8, 2023, and entitled “VERTICALLY-ARRANGED GATE ALL AROUND TRANSISTORS HAVING UNIFORM CELLCONTACT LIGHTLY-DOPED DRAIN REGIONS.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a memory device including vertically-arranged gate all around transistors having uniform cell contact junctions.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIG. 2 is a diagram of an example memory device including a plurality of vertically-arranged gate all around transistors having uniform cell contact lightly-doped drain regions.

FIGS. 3A-3C are diagrams illustrating example details related to the memory device of FIG. 2.

FIG. 4 is a diagram illustrating example details related to fabrication of the memory device of FIG. 2.

FIG. 5 is a flowchart of an example method of forming the memory device of including a plurality of vertically-arranged gate all around transistors having uniform cell contact lightly-doped drain regions.

FIGS. 6A-6X through 8A-8T are diagrammatic views showing formation of the memory device of FIG. 2, including stages of example processes of forming the memory device.

FIG. 9 is a diagrammatic view of an example memory device.

### DETAILED DESCRIPTION

In some cases, a memory device includes a field-effect transistor (FET), such as a gate all around (GAA) transistor, to control access to a storage cell (e.g., a capacitor) storing data within the memory device. The GAA transistor may include a channel and a gate structure that wraps around the entire channel, providing a more efficient control over the current flow through the channel relative to another FET having a gate structure that wraps around a portion of the channel. With the gate wrapped around the channel, the electric field is more concentrated and can better modulate the conductivity of the channel, leading to improved performance in terms of speed, power consumption, and noise.

A three-dimensional DRAM memory device may include a plurality of vertically-arranged GAA transistors (e.g., a plurality of vertically-arranged gate structures wrapping around a plurality of channel regions) and a corresponding plurality of vertically-arranged storage cell structures (e.g., a corresponding plurality of vertically-arranged stud capacitor structures).

Each GAA transistor may include a storage cell contact region. The storage cell contact region corresponds to a region where contact is made with an electrode of a storage cell (e.g., an electrode of a stud capacitor structure). In the storage cell contact region, the electrode may come into direct contact with a semiconductor material that allows for a flow of electric current (e.g., stored data) into and out of the storage cell structure and through a channel of the GAA transistor. In some implementations, the semiconductor material of the storage cell contact region is lightly doped with a dopant to improve and/or rather to modify an electric field near, or within, the channel region of the GAA transistor. In such a case, the storage cell contact region may be referred to as a cell contact lightly-doped drain region (CC LDD).

Forming the GAA transistor may include a combination of deposition, patterning, etching, and doping operations. In some implementations, the combination of operations includes defining widths of the CC LDD region by exhuming liner materials from a first trench and etching recesses of the liner material from a second trench, where the first trench and the second trench are on opposite sides of the CC LDD region. In the three-dimensional DRAM memory device, angles of the two trenches may, along the plurality of vertically-arranged GAA transistors, create a plurality of CC LDD regions that include an angled profile along the plurality of vertically-arranged GAA transistors. In other words, the plurality CC LDD regions may be formed to have non-uniform lengths (e.g., different lengths) at different depths of the two trenches.

In some implementations, the non-uniform lengths of the CC LDD regions reduce a performance of a GAA transistor. For example, if an increased (e.g., non-uniform) length of a CC LDD region causes the CC LDD region to excessively overlap with a gate of a GAA transistor, a capacitance between the gate and a drain terminal of the GAA transistor may rise to increase a likelihood of gate-induced drain leakage within the GAA transistor. Conversely, if a decreased (e.g., non-uniform) length of a CC LDD region causes the CC LDD region to excessively underlap with a gate of a GAA transistor, a channel of the GAA transistor may be insufficiently coupled to the gate and to increase a resistivity of the GAA transistor and decrease a resistive current between a drain terminal and a source terminal (e.g., Ids). In other words, failing to maintain uniform lengths of CC LDD regions throughout the GAA transistors may cause the three-dimensional DRAM device not satisfy thresholds related to capacitance, resistance, and or resistive current within the three-dimensional DRAM device.

Some implementations herein provide for a memory device and methods of formation. The memory device includes a plurality of storage cells arranged vertically and a plurality of corresponding GAA transistors. Methods of forming the memory device include using a single trench to remove a liner material and form recesses that define CC LDD regions of the GAA transistors. Using the single trench to remove the liner material and form the recesses that define the CC LDD region widths causes the CC LDD regions to be formed having substantially similar widths.

In this way, a uniformity of the CC LDD regions throughout the memory device is improved relative to CC LDD regions in another memory device that are defined by exhuming the liner material from a first trench and etching recesses of the liner material from a second, opposing trench. By improving the uniformity of the CC LDD regions, a performance of the memory device (e.g., a performance related to a capacitance, resistance, and/or a resistive current within the memory device) may improve to increase a yield of the device to a quality and/or a reliability threshold. By improving the yield of the device to the quality and/or the reliability threshold a consumption of resources for manufacturing a volume of the three-dimensional DRAM memory device (e.g., semiconductor manufacturing processing tools, raw materials, manpower, and/or computing resources) may be reduced.

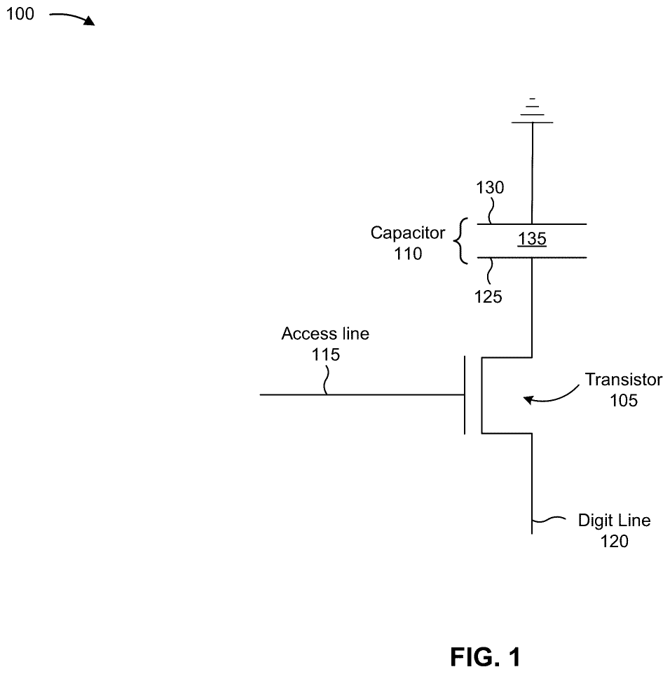

FIG. 1 is a circuit diagram of an example memory cell 100. In some implementations, the memory cell 100 is a dynamic random access memory cell. As illustrated in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, illustrated as an access line 115 (sometimes called a “word line”), and a digit line 120 (sometimes called a “bit line”).

The capacitor 110 includes a bottom electrode 125 and a top electrode 130 separated by an insulator 135. To write to (or program) the memory cell 100, the access line 115 may be activated, and a voltage may be applied across the capacitor 110 by controlling the voltage of the digit line 120 The applied voltage creates an electric field, and the atoms in the insulator 135 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 135 between the bottom electrode 125 and the top electrode 130).

To read the memory cell 100 (e.g., a state stored by the capacitor 110), the access line 115 may be activated. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

As indicated above, FIG. 1 is provided as an example. Other examples may differ from what is described with respect to FIG. 1.

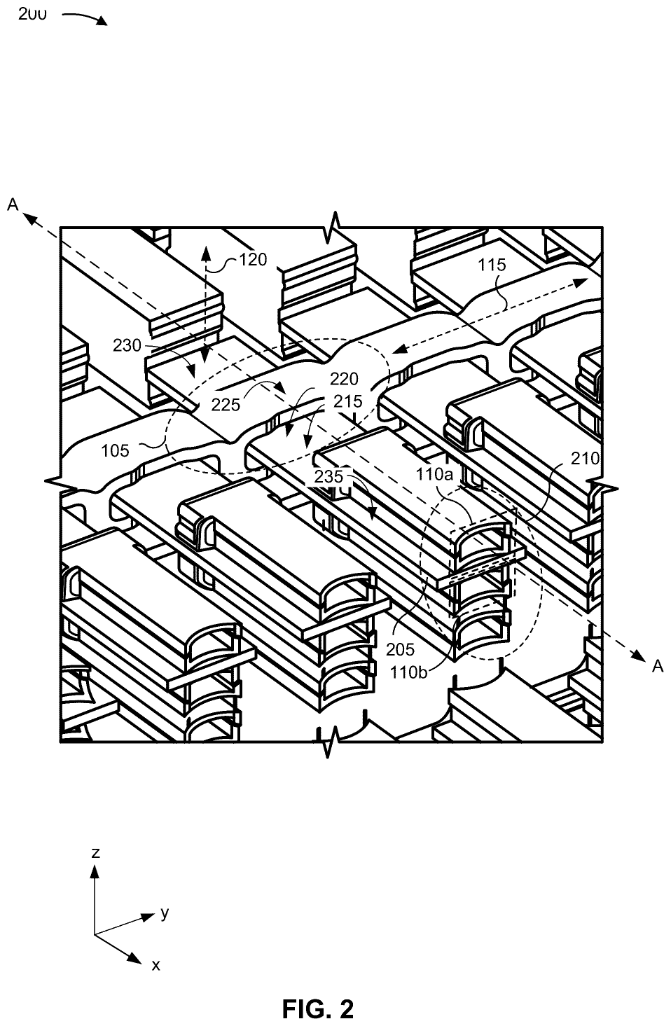

FIG. 2 is a diagram illustrating an example memory device 200 including vertically-arranged gate all around transistors having uniform CC LDD regions. FIG. 2 illustrates example structural aspects of the memory cell 100 of FIG. 1. Furthermore, FIG. 2 may exclude portions of the memory device 200 for clarity purposes. In some implementations, FIG. 2 is a three-dimensional DRAM memory device including a plurality of vertically-arranged GAA transistors. FIG. 2 includes a section line A-A for reference when describing additional details related to section views of the memory device 200.

The memory device 200 includes a cantilever structure 205. The cantilever structure may include a semiconductor material, such as a silicon material or a material including a type III/type V element, among other examples.

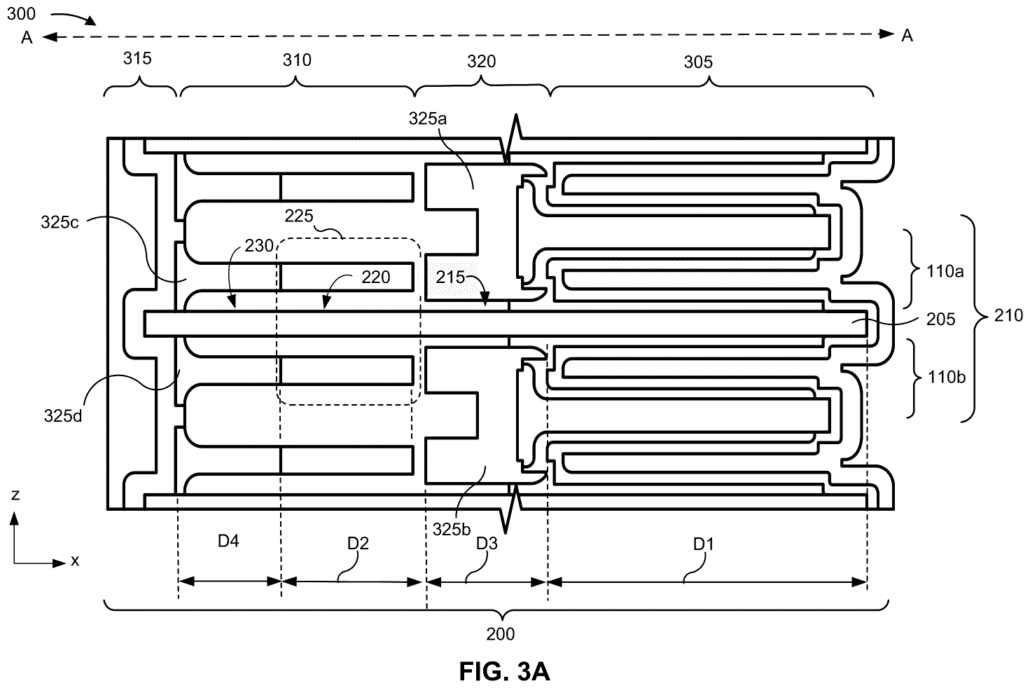

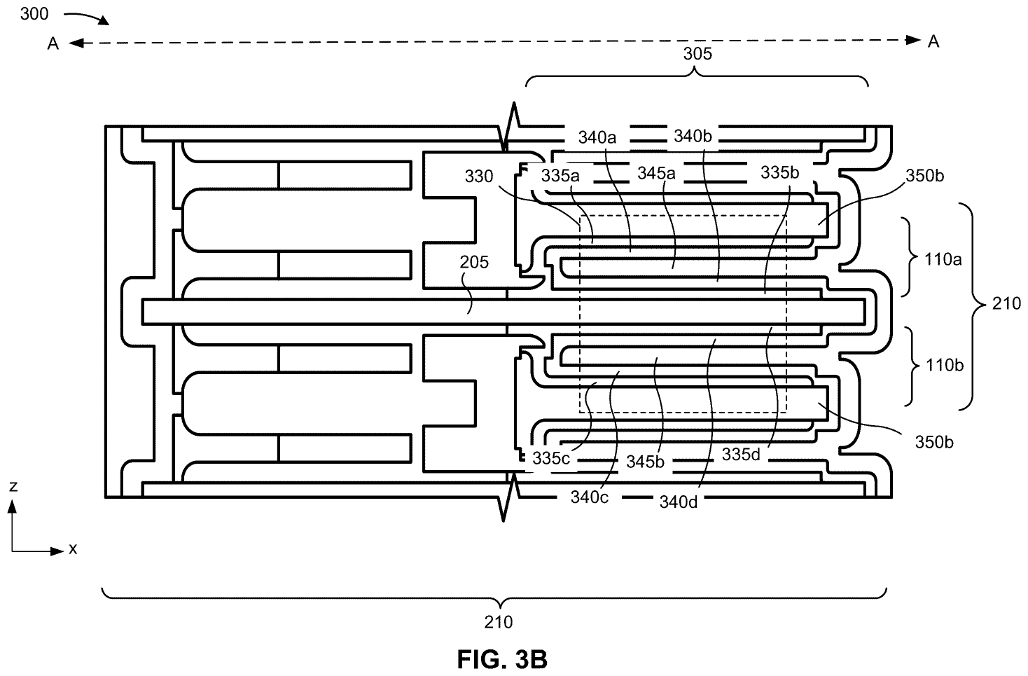

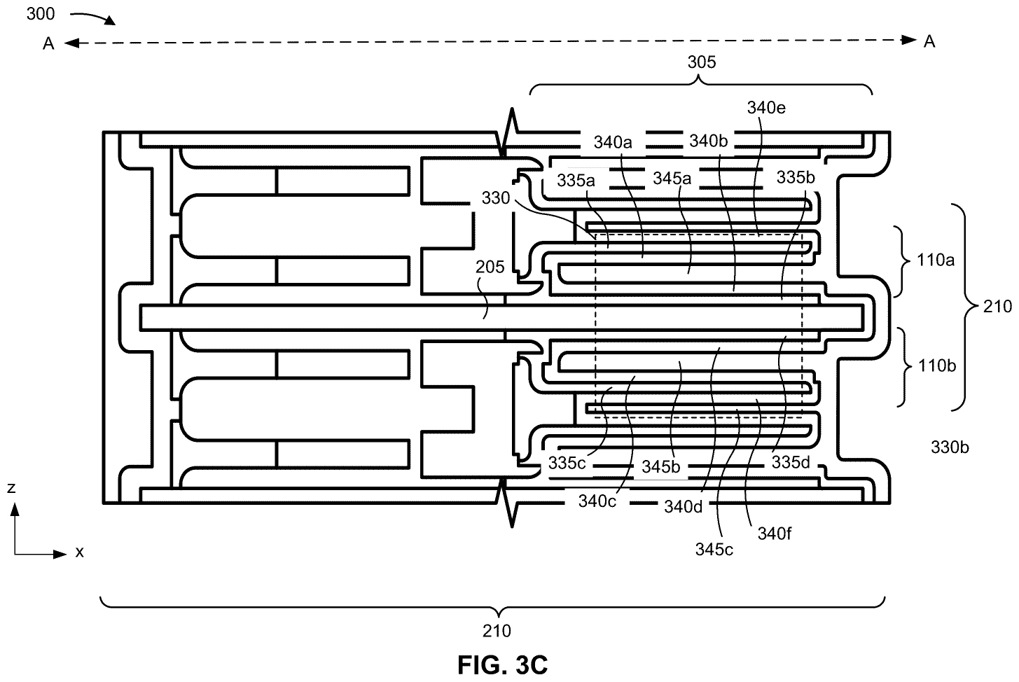

As illustrated in FIG. 2, a storage cell 210 including a capacitor 110a and a capacitor 110b (e.g., a stud capacitor storage cell) is on an end the cantilever structure 205. The capacitor 110a (e.g., a first capacitor structure) is connected to a topside surface of the cantilever structure 205. The capacitor 110b (e.g., a second capacitor structure) is connected to an underside surface of the cantilever structure 205. As described in greater detail in connection with FIGS. 3A-3C, the capacitor 110a and/or the capacitor 110b may include a plurality regions of a high-K dielectric layer interspersed with a plurality regions of bottom electrode layers and/or top electrode layers. In some implementations, the arrangement of the capacitors 110a and 110b (e.g., stacked capacitors) reduces amount of space consumed by the storage cell 210 relative to another storage cell including a single cell.

The cantilever structure 205 includes a CC LDD region 215 and a channel region 220. As illustrated in FIG. 2, the capacitor 110a and the capacitor 110b connect with the CC LDD region 215 of the cantilever structure 205. The CC LDD region 215 is a lightly doped (n- or p-) region that provides a low-resistance path for electrical current to flow between the capacitors 110a and 110b and the channel region 220.

As further illustrated in FIG. 2, a gate structure 225 (e.g., a transistor gate structure) wraps around the channel region 220 of the cantilever structure 205. The gate structure 225 (e.g., a gate all around or GAA structure) may include a conductive material such as a polysilicon material, a metal material, or another electrically conductive material.

On a side of the gate structure 225 that is opposite the CC LDD region 215, the cantilever structure 205 includes a digit line lightly-doped drain (DL LDD) region 230. The DL LDD region 230 is a lightly doped (n- or p-) region that provides a low-resistance path for electrical current to flow between the channel region 220 and a digit line structure.

Between the capacitors 110a and 110b, the cantilever structure 205 includes an electrode contact region 235. The electrode contact region 235 may make contact with one or more electrode layers (e.g., bottom electrode layers or top electrode layers) of the capacitors 110a and/or 110b.

The memory device 200 of FIG. 2 includes multiple features that correspond to features included in the memory cell 100 of FIG. 1. For example, the channel region 220 and the gate structure 225, in combination, form a GAA transistor that corresponds to the transistor 105 of FIG. 1. Additionally, or alternatively, the storage cell 210 (including the capacitors 110 and 110b) corresponds to the capacitor 110 of FIG. 1. Additionally, or alternatively, the gate structure 225 is included as part of the access line 115 of FIG. 1. Additionally, or alternatively, the DL LDD region 230 may connect to the digit line 120 of FIG. 1.

As indicated above, FIG. 2 is provided as an example. Other examples may differ from what is described with respect to FIG. 2.

FIGS. 3A-3C are diagrams illustrating example details 300 related to the memory device 200 of FIG. 2A. FIGS. 3A-3C illustrate side section-views of the memory device 200 that correspond to the section line A-A of FIG. 2. FIGS. 3A-3C include a storage cell region 305, a transistor region 310, and a DL region 315. The storage cell region 305 may include a plurality of vertically-arranged storage cell(s) 210 (e.g., including a plurality of the capacitors 110 of FIG. 1). The transistor region 310 may include a same plurality of vertically arranged transistors (e.g., a same plurality of the transistor 150 of FIG. 1) including the gate structure 225 (e.g., a GAA structure).

The digit line region 315 may include one or more digit line structures (e.g., structures included in the digit line 120 of FIG. 1). Furthermore, and as illustrated in FIG. 3A, a cell contact (CC) junction region 320 may be between the transistor region 310 and the DL region 315.

As illustrated in FIG. 3A, the memory device 200 includes the cantilever structure 205 passing through the gate structure 225. The cantilever structure 205 includes the channel region 220, the CC LDD region 215, and the DL LDD region 230. Furthermore, the storage cell 210 (e.g., including the capacitor 110a and the capacitor 110b) is at an end of the cantilever structure 205.

As illustrated in FIG. 3A, the electrode contact region 235 (e.g., a capacitor electrode length) has a width D1. Based on a design of the memory device 200, and/or process capabilities of semiconductor manufacturing tools used to manufacture the memory device 200 (lithography nodes, accuracy characteristics, repeatability characteristics, and or tolerance stacks, among other examples), the width DI may be included in a range of approximately 20 nanometers to approximately 300 nanometers. However, other values and ranges for the width D1 are included within the scope of the present disclosure.

As further illustrated in FIG. 3A, the gate structure 225 has a width D2 (e.g., a gate length). Based on a design of the memory device 200, and/or process capabilities of semiconductor manufacturing tools used to manufacture the memory device 200, the width D2, may be included in a range of approximately 10 nanometers to approximately 120 nanometers.

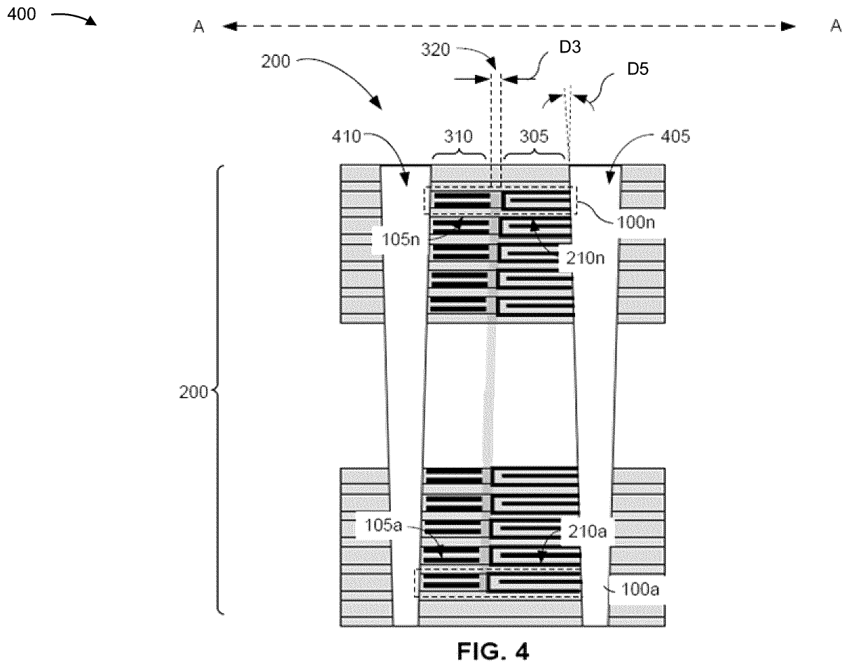

As described in greater detail in connection with FIGS. 4-7T and elsewhere herein, and as illustrated in FIG. 3A, the memory device 200 includes a liner structure 325a (e.g., a first liner structure) that is above the cantilever structure 205. The memory device 200 further includes a liner structure 325b (e.g., a second liner structure) that is below the liner structure 325a. The cantilever structure 205 includes the CC LDD region 215 (e.g., between the liner structures 325a and 325b). In some implementations, the CC LDD region 215 has a width D3 that is included in a range of approximately 10 nanometers to approximately 100 nanometers. However, other values and ranges for the width D3 are within the scope of the present disclosure.

In a case where the width D3 of the liner structures 325a and 325b is substantially similar across a plurality of vertically-arranged memory cells, the width(s) D3 across the plurality of vertically-arranged memory cells (e.g., the width D3 of each CC LDD region 215) may be substantially similar (e.g., substantially uniform). Having such a uniformity (e.g., of the width D3) improves the performance of the memory device 200 (e.g., a performance related to a capacitance, resistance, and/or a resistive current within the memory device) relative to another memory device having lesser uniformity. In this way, a yield of the memory device 200 to a quality and/or a reliability threshold may improve. By improving the yield of the memory device 200 to the quality and/or the reliability threshold a consumption of resources for manufacturing a volume of the three-dimensional DRAM memory device (e.g., semiconductor manufacturing processing tools, raw materials, manpower, and/or computing resources) may be reduced.

As described in greater detail in connection with FIGS. 4-7T and elsewhere herein, and as illustrated in FIG. 3A, the memory device 200 further includes a liner structure 325c (e.g., a third liner structure) that is above the cantilever structure 205. The memory device 200 further includes a liner structure 325d (e.g., a fourth liner structure) that is below the cantilever structure 205. The cantilever structure 205 includes the DL LDD region 230 (e.g., between the liner structures 325c and 325b). The liner structures DL LDD region may have width D4 that is included in a range of approximately 10 nanometers to approximately 100 nanometers. However, other values and ranges for the width D4 are within the scope of the present disclosure.

In a case where the width D4 of the liner structures 325c and 325d is substantially similar across a plurality of vertically-arranged memory cells, the width(s) D4 across the plurality of vertically-arranged memory cells (e.g., the width D4 of each DL LDD region 230) may be substantially similar (e.g., substantially uniform). Having such a uniformity (e.g., of the width D4) improves the performance of the memory device 200 (e.g., a performance related to a capacitance, resistance, and/or a resistive current within the memory device) relative to another memory device having lesser uniformity. In this way, a yield of the memory device 200 to a quality and/or a reliability threshold may improve. By improving the yield of the memory device 200 to the quality and/or the reliability threshold a consumption of resources for manufacturing a volume of the three-dimensional DRAM memory device (e.g., semiconductor manufacturing processing tools, raw materials, manpower, and/or computing resources) may be reduced.

Turning to FIG. 3B, and as illustrated in the storage cell region 305, a layered structure 330 of the storage cell 210 may include a combination of interspersed conductive and/or dielectric layers. For example, and as illustrated in FIG. 3B, the layered structure 330 includes four (4) bottom electrode (BE) layer portions 335a-335d interspersed with four (4) high-k (HK) dielectric layer portions 340a-340d.

The BE layer portions 335a-335d may include a conductive material such as a titanium nitride material (TiN), among other examples. In some implementations, the BE layer portions 335a-335d correspond to the bottom electrode 125 of FIG. 1.

The HK dielectric layer portions 340a-340d may include a dielectric material such as a hafnium dioxide material (HfO₂), among other examples. In some implementations, the HK dielectric layer portions 340a-340d correspond to the insulator 135 of FIG. 1.

The layered structure 330 of FIG. 3B may further include a quantity of two (2) top electrode (TE) layer portions 345 and 345b. The TE layer portions 345 and/or 345b may include a conductive material such as a tungsten material (W), among other examples. In some implementations, the TE layer portions 345 and/or 345b correspond to the top electrode 130 of FIG. 1.

In FIG. 3B, two (2) inter-tier dielectric (ITD) layer portions 350a and 350b may be included in the layered structure 330. The ITD layer portions 350a and/or 350b may include a dielectric material such as a silicon dioxide material (SiO₂), among other examples.

FIG. 3C shows another example of the layered structure 330. As illustrated in the side section-view of FIG. 3C, the layered structure 330 of the storage cell 210 may include a combination of interspersed conductive and/or dielectric layers. In contrast to FIG. 3B, the layered structure 330 includes the four (4) BE layer portions 335a-335d interspersed with six (6) HK dielectric layer portions 340a-340f. Furthermore, and in contrast to FIG. 3B, the layered structure 330 of FIG. 3C includes a quantity of three (3) TE layer portions 345a-345c.

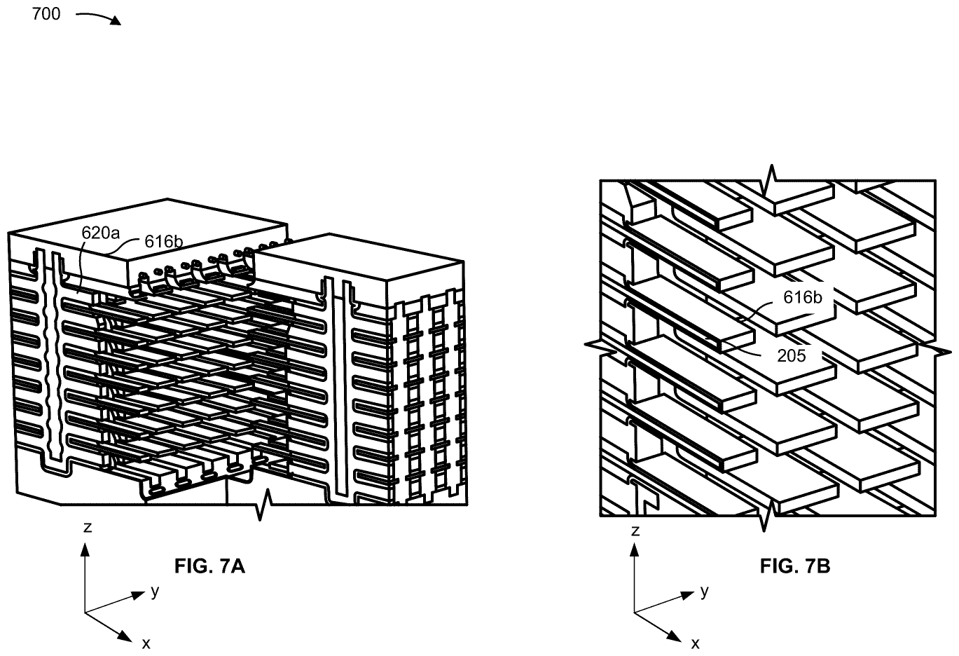

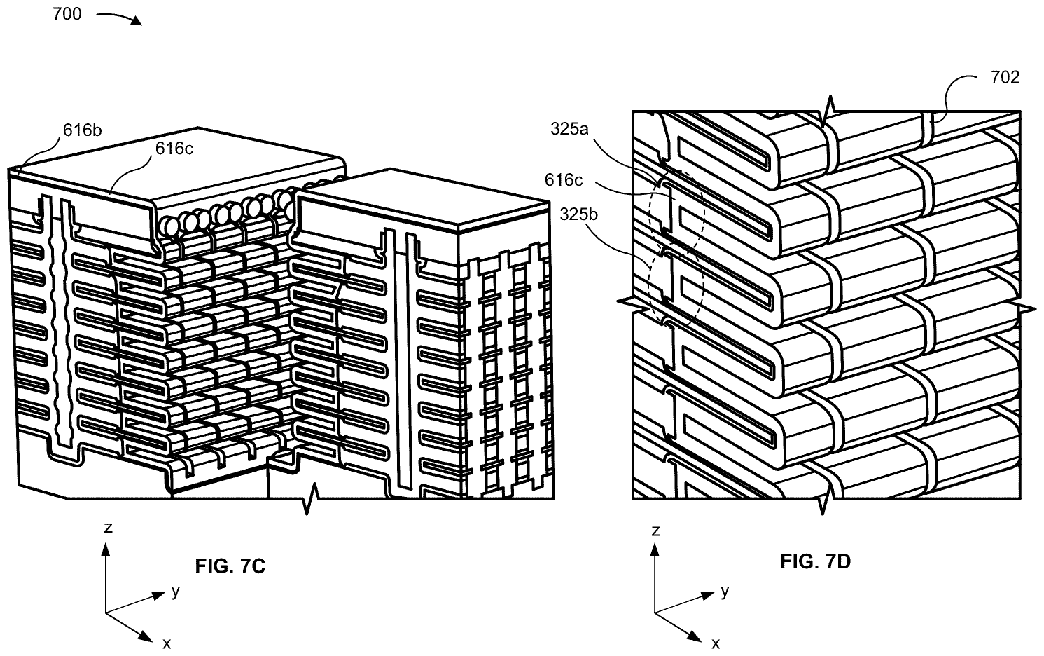

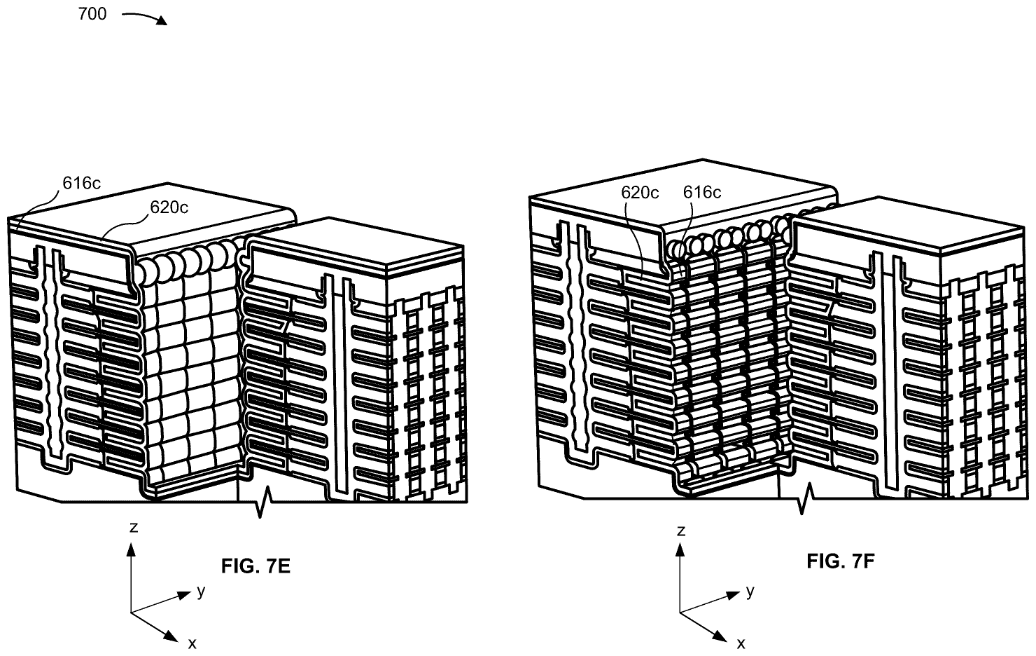

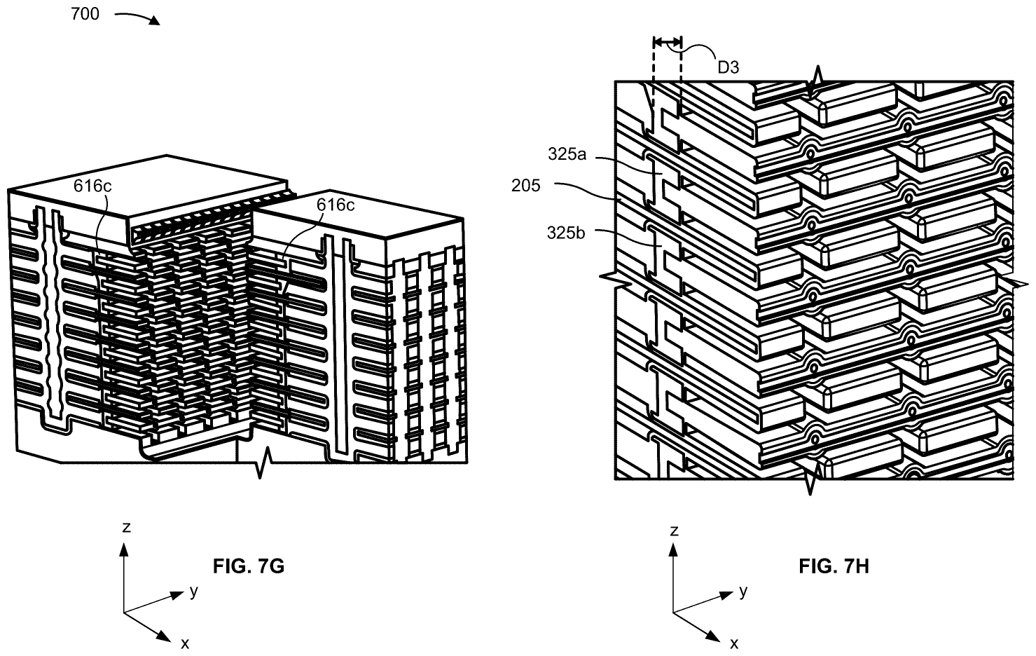

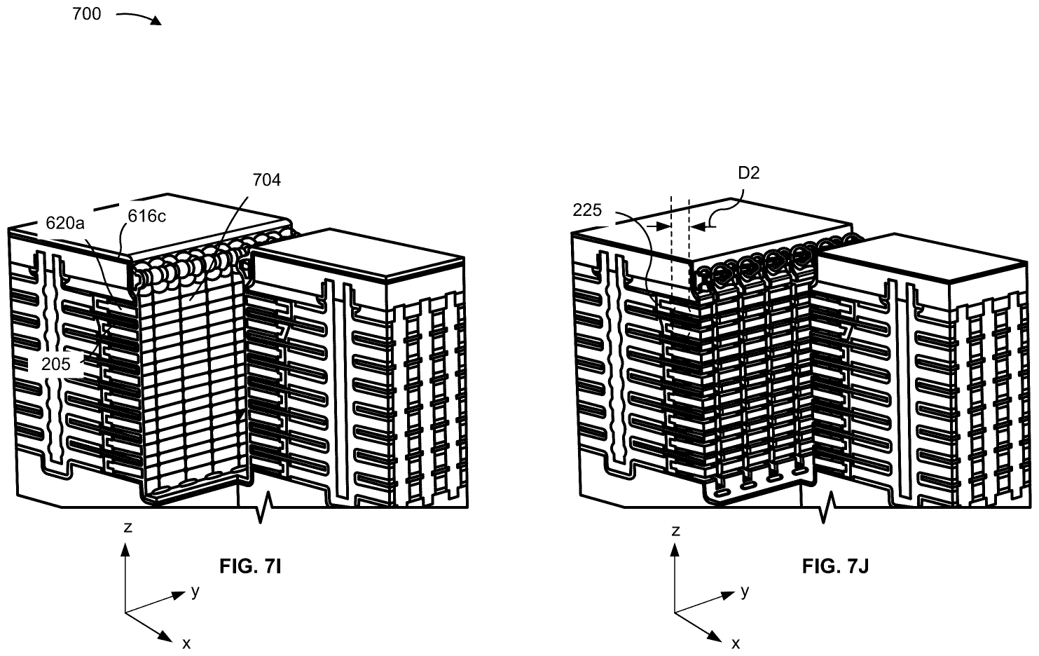

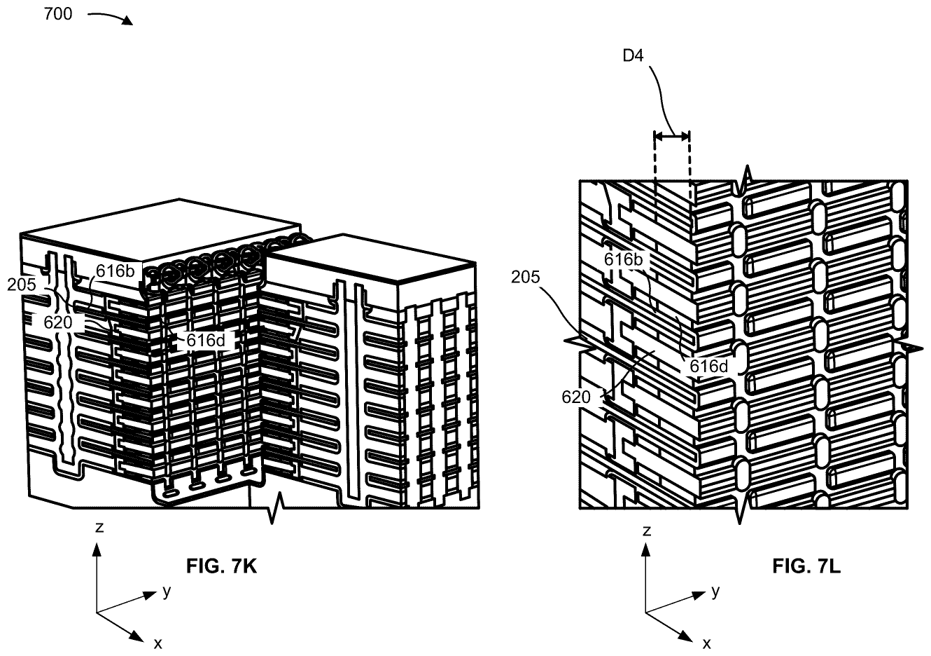

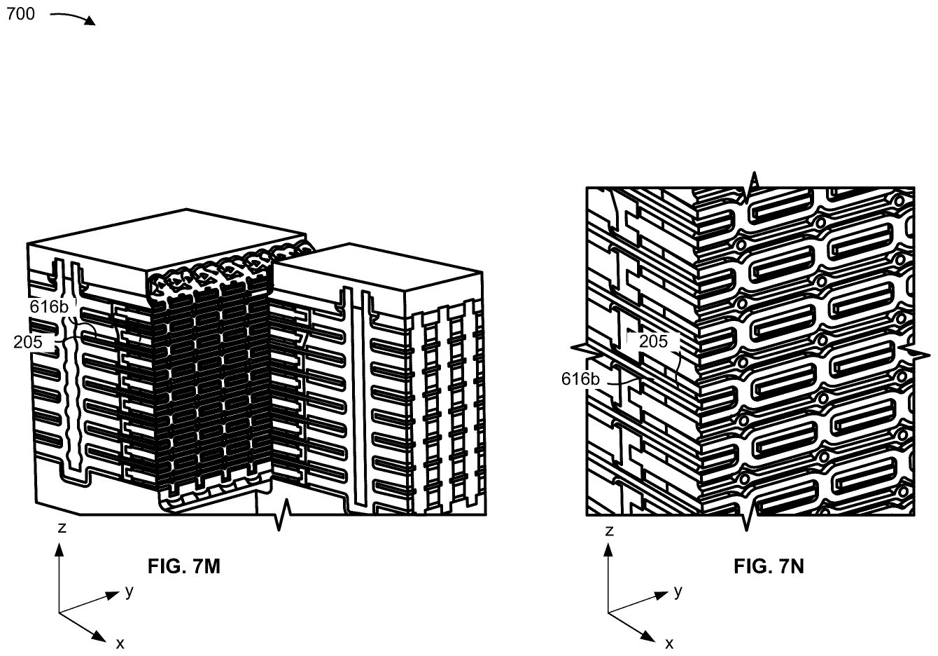

As illustrated in FIG. 3C, and in contrast to FIG. 3B, the layered structure 330 excludes the ITD layer portions 350a and 350b. As described in greater detail in connection with FIGS. 7A-7S, an etching operation may remove the ITD layer portions 350a and/or 350b to accommodate formation of additional HK layer portions 340e, the HK layer portion 340f, and/or the TE layer portion 345c.

As shown in FIGS. 3B and 3C, one or more of the ITD layer portions 350a and/or 350b may be between co-facing portions of the BE layer portions 335a-335d.

As indicated above, FIGS. 3A-3C are provided as examples. Other examples may differ from what is described with respect to FIGS. 3A-3C.

FIG. 4 is a diagram illustrating example details 400 related to fabrication of the memory device 200 of FIG. 2. FIG. 4 illustrates a side section-view of the memory device 200 that corresponds to the section line A-A of FIG. 2. As illustrated in FIG. 4, the memory device 200 includes a plurality of vertically-arranged memory cells 100a-100n. The plurality of vertically-arranged memory cells 100a-100n includes a corresponding plurality vertically-arranged of storage cells 210a-210n within the storage cell region 305 of the memory device 200. The plurality of vertically-arranged memory cells 100a-100n further includes a corresponding plurality of vertically-arranged transistors 105a-105n (e.g., GAA transistors) within the transistor region 310 of the memory device.

As illustrated in FIG. 4, and in some implementations, formation of the memory device 200 may include forming a high aspect ratio trench 405 adjacent to the storage cell region 305 and forming a high aspect ratio trench 410 adjacent to the transistor region 310.

The high aspect ratio trenches 405 and 410 each include a sloped sidewall that is tapered at an angle D5. As an example, the angle D5 may be included in arrange of approximately 0.05 degrees to approximately 0.15 degrees. However, other values and ranges for the angle D5 are within the scope of the present disclosure.

As illustrated in FIG. 4, the junction region 320 is between the storage cell region 305 and the transistor region 310. Some manufacturing techniques that form features within the memory device 200 may include performing time-based lateral etching operations within each of the high aspect ratio trenches 405 and 410. Based on the angle D5 and performing the time-based lateral etching operations in both high aspect ratio trenches 405 and 410, a uniformity of features within the storage cell region 305 of memory device 200 (e.g., the CC LDD region(s) 215) may be insufficient to satisfy a performance threshold of the memory device 200.

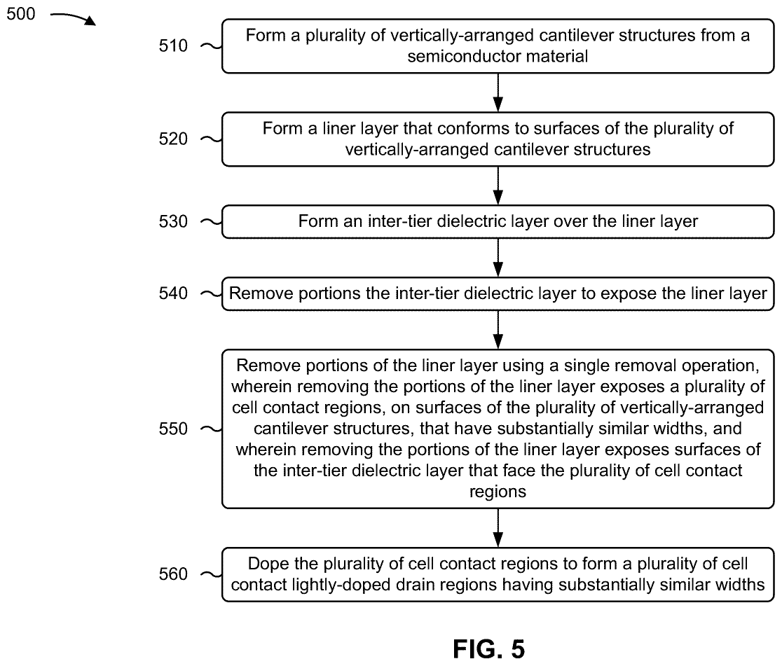

As an alternative, and as described in greater detail in connection with FIGS. 5A-7T, formation of the storage cell(s) 210 within the storage cell region 305 may include performing a lateral etching operation in the high aspect ratio trench 405 (and not both of the high aspect ratio trenches 405 and 410). Furthermore, and in contrast to being time-based, the lateral etching operation may include using features within the junction region 320 (e.g., the liner structures 325a and/or 325b having the width D3) as etch stops. Such a technique may increase a uniformity of the CC LDD region(s) 215 of the storage cell(s) 210.

In this way, a performance of the memory device 200 (e.g., a performance related to a capacitance, resistance, and/or a resistive current within the memory device 200) may improve to increase a yield of the memory device 200 to a quality and/or a reliability threshold. By improving the yield of the memory device 200 to the quality and/or the reliability threshold. a consumption of resources for manufacturing a volume of the memory device 200 (e.g., semiconductor manufacturing processing tools, raw materials, manpower, and/or computing resources) may be reduced.

In combination with FIGS. 1-3C, FIG. 4 illustrates a memory device (e.g., the memory device 200) that includes a plurality of silicon cantilever structures (e.g., the cantilever structure(s) 205) arranged vertically and a storage cell (e.g., the storage cell 210) on an end of each of the plurality of silicon cantilever structures. Each storage cell includes a first capacitor structure (e.g., the capacitor 110a) connected to a topside surface of a corresponding silicon cantilever structure. Each first capacitor structure includes a first plurality of high-K dielectric layer portions (e.g., the HK dielectric layer portions 340a, 340b, and/or 340e) that are vertically-arranged and interspersed with a first plurality of electrode layer portions (e.g., the BE electrode layer portion 335a, the BE electrode layer portion 335b, and/or the TE electrode layer portion 345a), where each of first plurality of high-K dielectric layer portions is approximately parallel to the topside surface. Each storage cell further includes second capacitor structure (e.g., the capacitor 110b) connected to an underside surface of the corresponding silicon cantilever structure. Each second capacitor structure includes a second plurality of high-K dielectric layer portions (e.g., the HK dielectric layer portions 340c, 340d, and/or 340f) that are vertically-arranged and interspersed with a second plurality of electrode layer portions (e.g., the BE electrode layer portion 335c, the BE layer portion 335d, the TE layer portion 345b, and/or the TE layer portion 345c), where each of the second plurality of high-K dielectric layer portions is approximately parallel to the underside surface.

Additionally, or alternatively and combination with FIGS. 1-3C, FIG. 4 illustrates a memory device (e.g., the memory device 200) that includes a plurality of storage cells (e.g., the storage cells 210a-210n) that are arranged vertically. The memory device includes plurality of corresponding gate all around transistors (e.g., the transistors 105a-105n) arranged adjacent to the plurality of storage cells. The memory device includes a plurality of corresponding cell contact lightly-doped drain regions (e.g., the CC LDD region(s) 215) connecting the plurality of storage cells and the plurality of corresponding gate all around transistors, where the plurality of corresponding cell contact lightly-doped drain regions have substantially similar widths (e.g., substantially similar width(s) D3).

As indicated above, FIG. 4 is provided as an example. Other examples may differ from what is described with respect to FIG. 4.

FIG. 5 is a flowchart of an example method 500 of forming the memory device of including a plurality of vertically-arranged gate all around transistors having uniform cell contact lightly-doped drain regions. In some implementations, one or more process blocks of FIG. 5 may be performed by various semiconductor manufacturing equipment. Furthermore, and in some implementations, the memory device is the memory device 200 described in connection with FIGS. 1-4.

As illustrated in FIG. 5, the method 500 may include forming a plurality of vertically-arranged cantilever structures from a semiconductor material (block 510). As further illustrated in FIG. 5, the method 500 may include forming a liner layer that conforms to surfaces of the plurality of vertically-arranged cantilever structures (block 520). As further illustrated in FIG. 5, the method 500 may include forming an inter-tier dielectric layer over the liner layer (block 530). As further illustrated in FIG. 5, the method 500 may include removing portions the inter-tier dielectric layer to expose the liner layer (block 540). As further illustrated in FIG. 5, the method 500 may include removing portions of the liner layer using a single removal operation, wherein removing the portions of the liner layer exposes a plurality of cell contact regions, on surfaces of the plurality of vertically-arranged cantilever structures, that have substantially similar widths, and wherein removing the portions of the liner layer exposes surfaces of the inter-tier dielectric layer that face the plurality of cell contact regions (block 550). As further illustrated in FIG. 5, the method 500 may include doping the plurality of cell contact regions to form a plurality of cell contact lightly-doped drain regions having substantially similar widths (block 560).

The method 500 may include additional aspects, such as any single aspect or any combination of aspects described below and/or in connection with one or more other methods described elsewhere herein.

In a first aspect, forming the liner layer includes depositing a layer of a silicon nitride material.

In a second aspect, alone or in combination with the first aspect, the single removal operation that removes the portions of the liner layer includes performing an etching operation in a trench that is adjacent to the plurality of vertically-arranged cantilever structures, wherein the etching operation laterally etches the liner layer.

In a third aspect, alone or in combination with one or more of the first and second aspects, doping the plurality of cell contact regions includes performing a gas phase doping operation or a silicidation doping operation.

In a fourth aspect, alone or in combination with one or more of the first through third aspects, the method 500 includes forming a storage cell on an end of each of the plurality of vertically-arranged cantilever structures.

In a fifth aspect, alone or in combination with one or more of the first through fourth aspects, forming the storage cell includes forming a first capacitor on an exposed topside surface of a cell contact lightly-doped drain region, wherein forming the first capacitor includes self-aligning the first capacitor to the cell contact lightly-doped drain region, and forming a second capacitor on an exposed underside surface of the cell contact lightly-doped drain region, wherein forming the second capacitor includes self-aligning the second capacitor to the cell contact lightly-doped drain region.

In a sixth aspect, alone or in combination with one or more of the first through fifth aspects, forming the storage cell includes forming bottom electrode layer portions on the exposed topside surface of the cell contact lightly-doped drain region, on the exposed underside surface of the cell contact lightly-doped drain region, on an exposed surface of the inter-tier dielectric layer facing the exposed topside surface of the cell contact lightly-doped drain region, and on an exposed surface of the inter-tier dielectric layer facing the exposed underside surface of the cell contact lightly-doped drain region.

In a seventh aspect, alone or in combination with one or more of the first through sixth aspects, forming the storage cell further includes forming a high-K dielectric layer on the bottom electrode layer portions.

In an eighth aspect, alone or in combination with one or more of the first through seventh aspects, forming the high-K dielectric layer on the bottom electrode layer portions includes forming at least four high-K dielectric layer portions that are vertically-arranged and approximately parallel to one another.

In a ninth aspect, alone or in combination with one or more of the first through eighth aspects, forming the storage cell further includes forming top electrode layer portions between co-facing portions of the high-K dielectric layer.

In a tenth aspect, alone or in combination with one or more of the first through ninth aspects, forming the top electrode layer portions between co-facing portions of the high-K dielectric layer includes forming at least two top electrode layer portions that are vertically-arranged and approximately parallel to one another.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming memory device 200, an integrated assembly that includes the memory device 200, any part described herein of the memory device 200, and/or any part described herein of an integrated assembly that includes the memory device 200. For example, the method 500 may include forming one or more of the cantilever structure(s) 205, one or more of the liner structures 325a and/or 325b, and/or one more of the CC LDD region(s) 215.

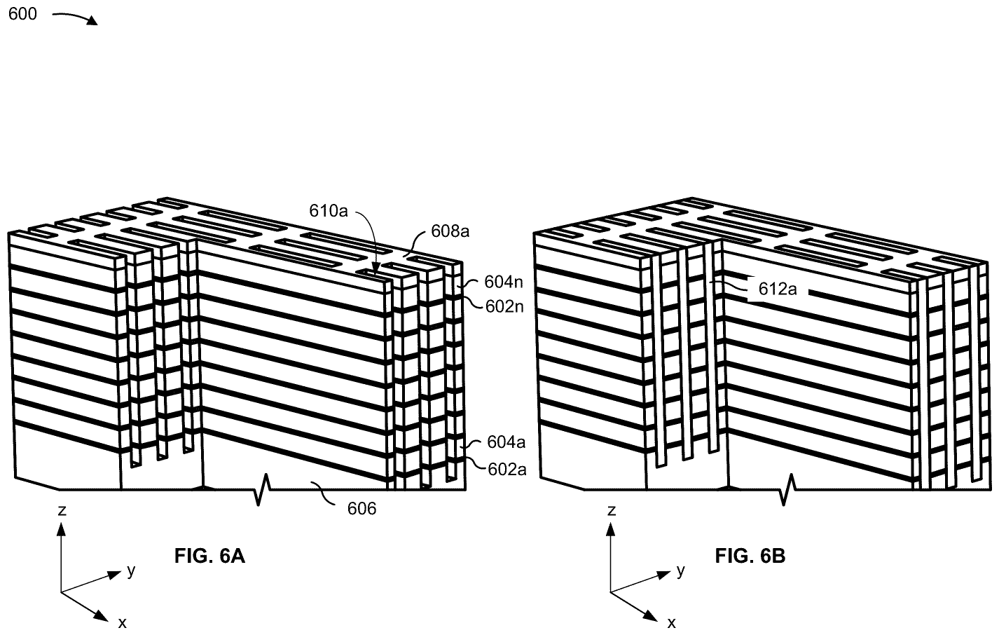

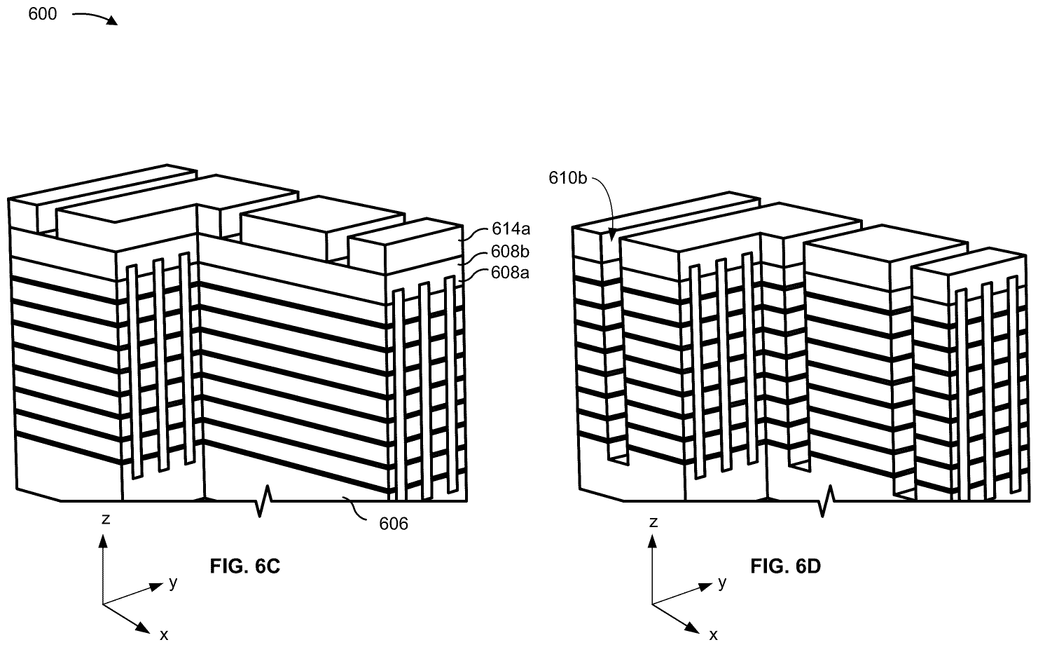

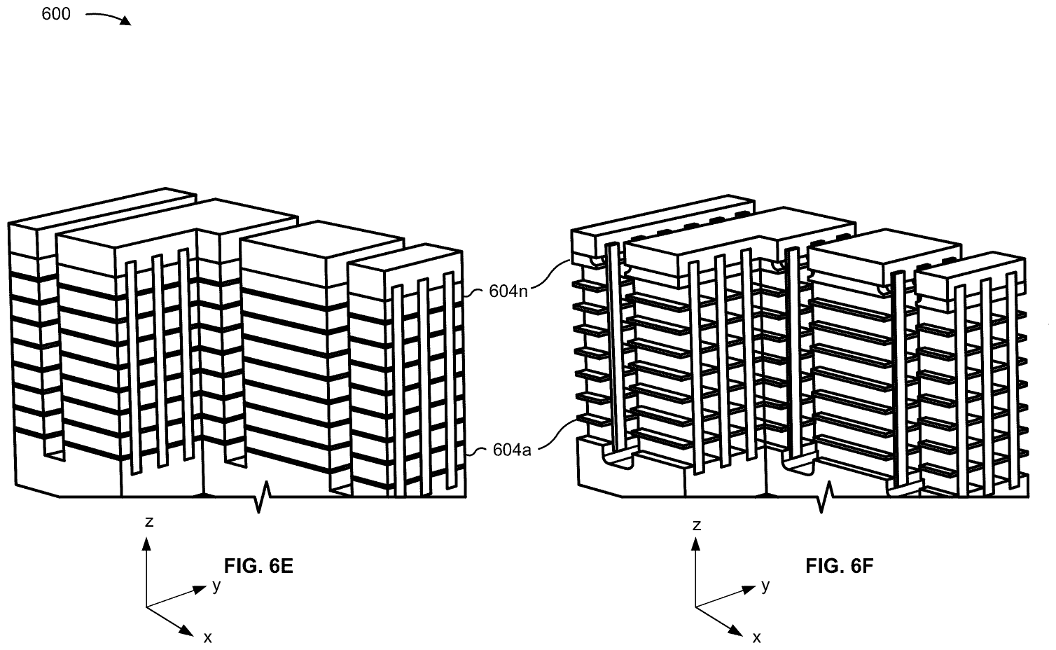

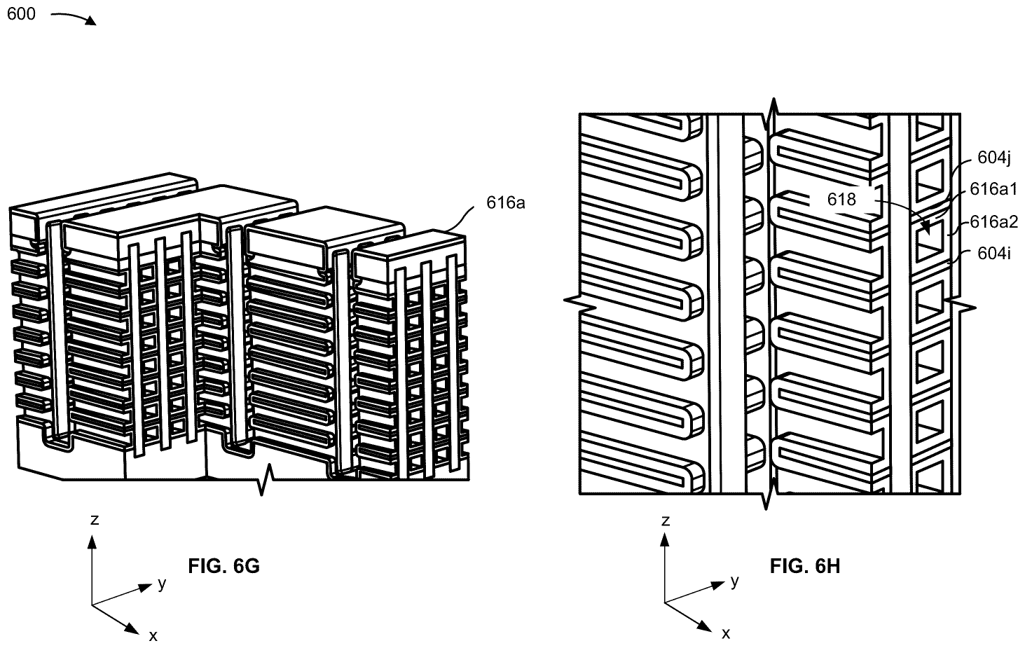

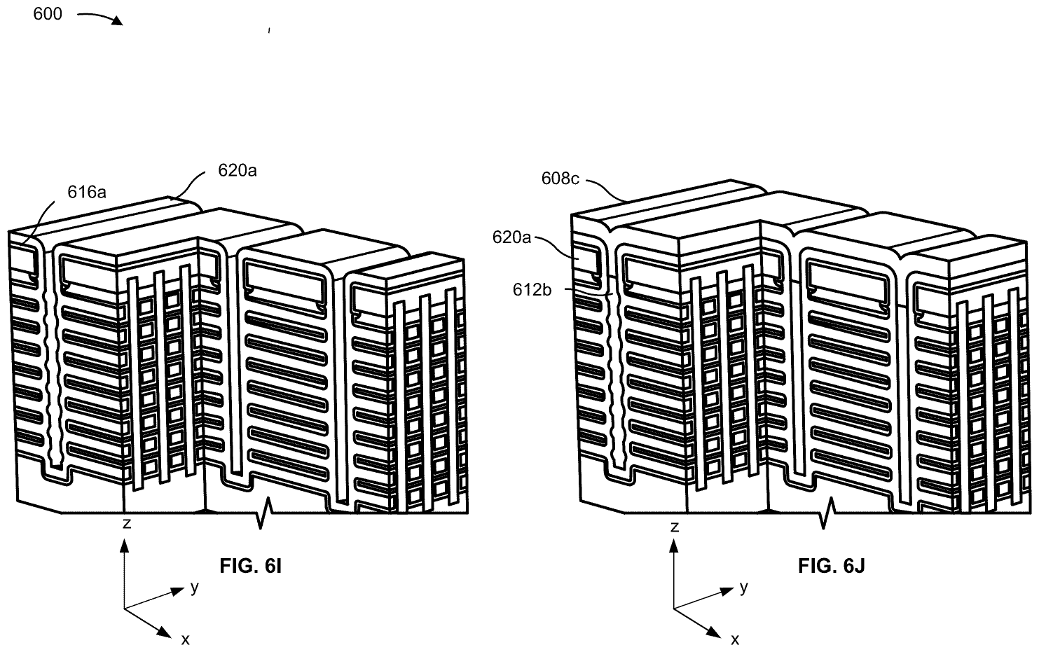

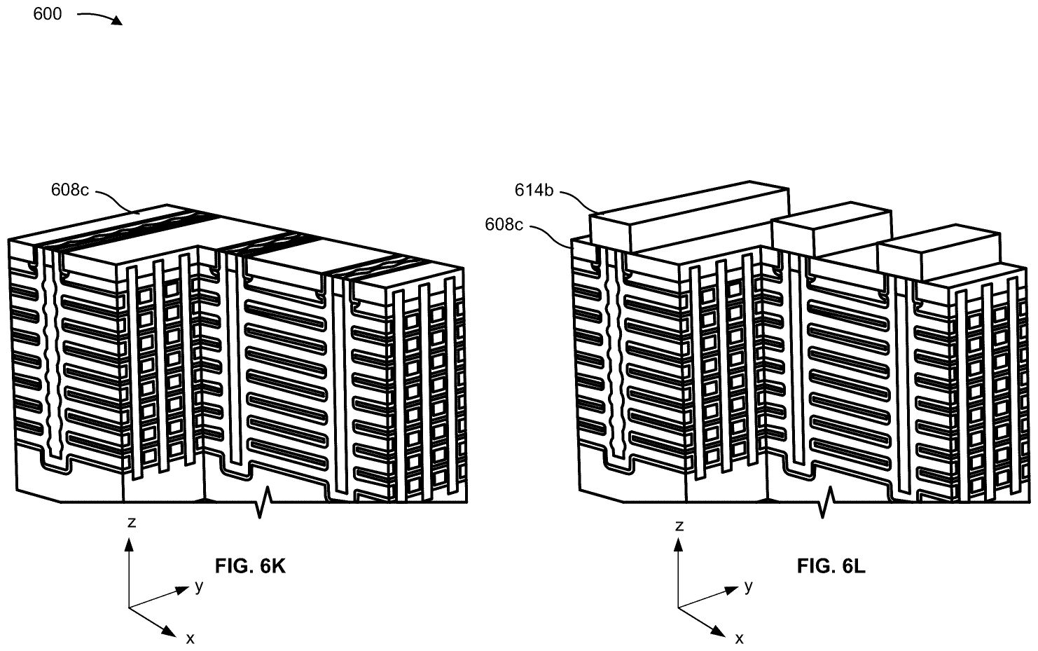

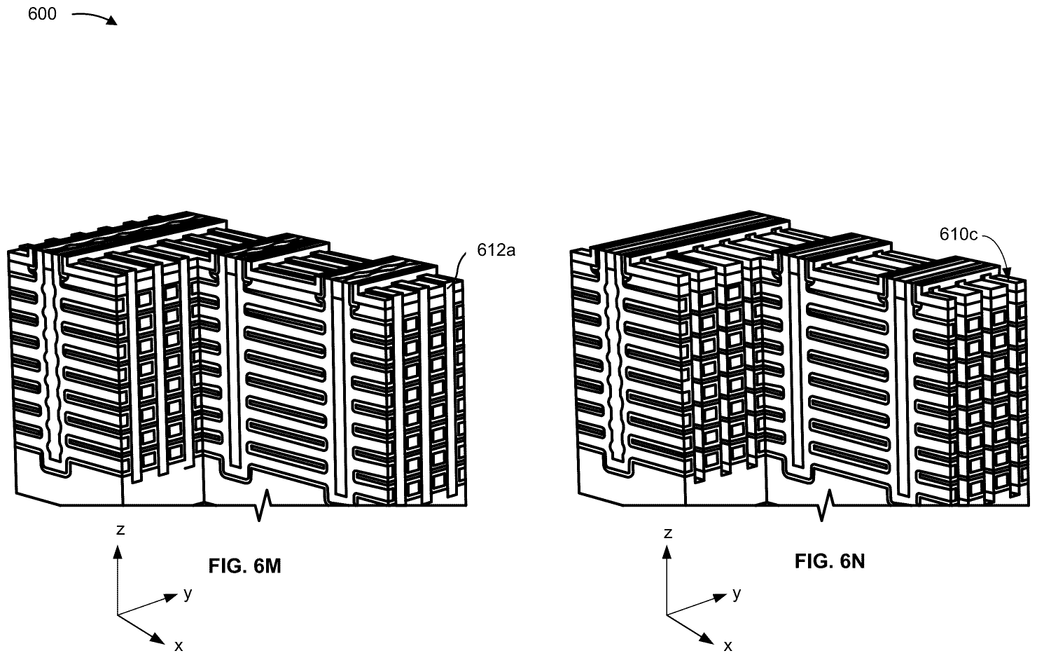

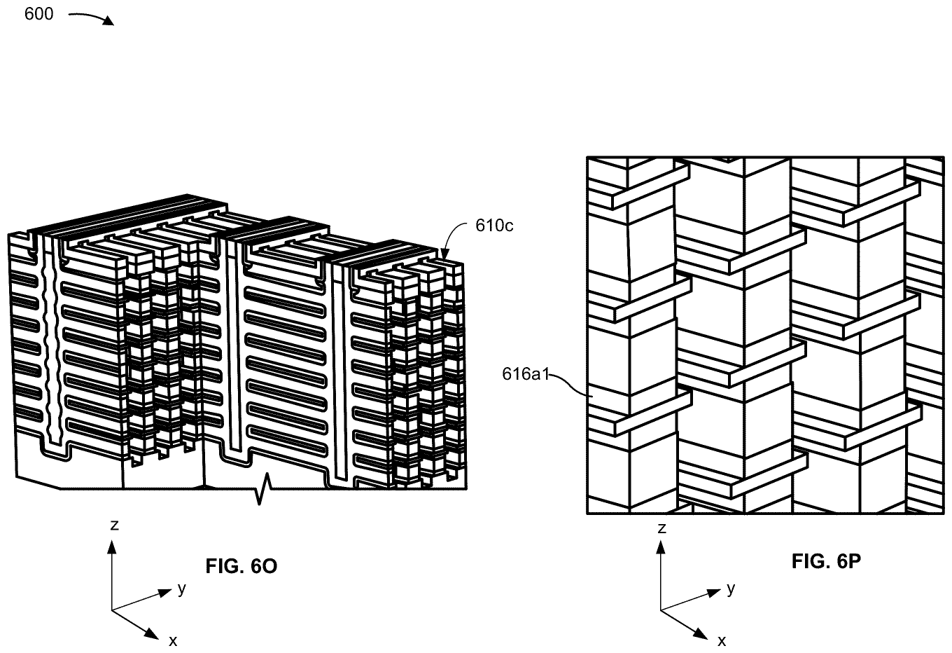

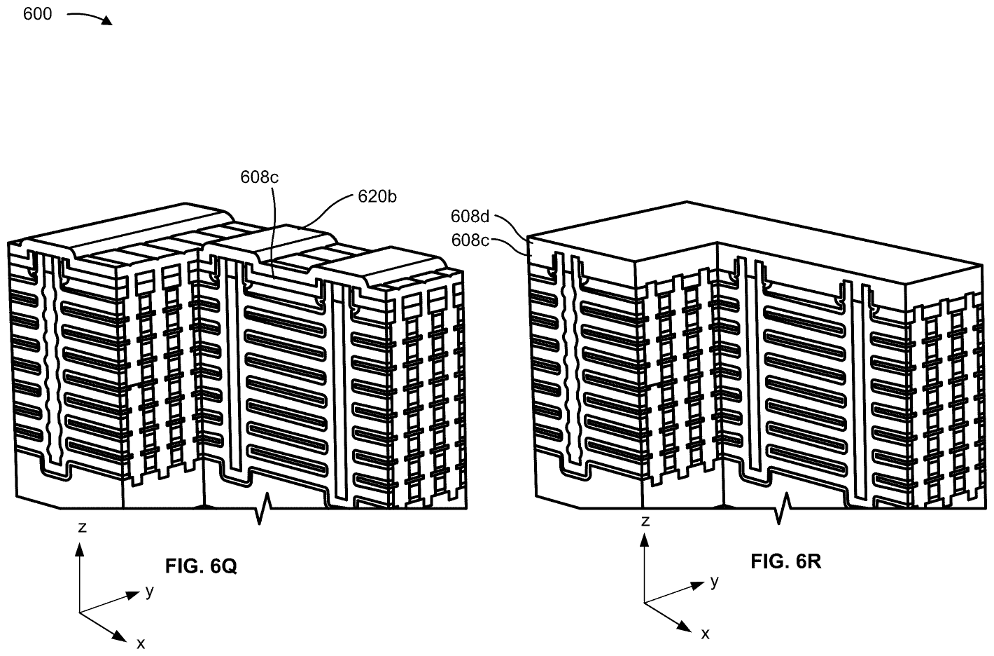

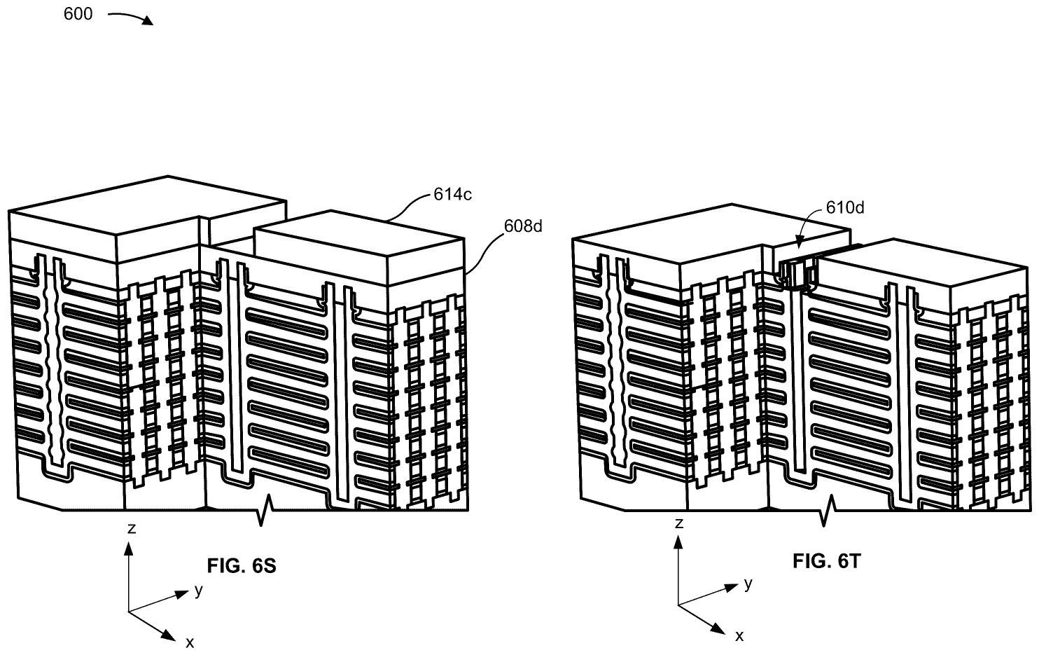

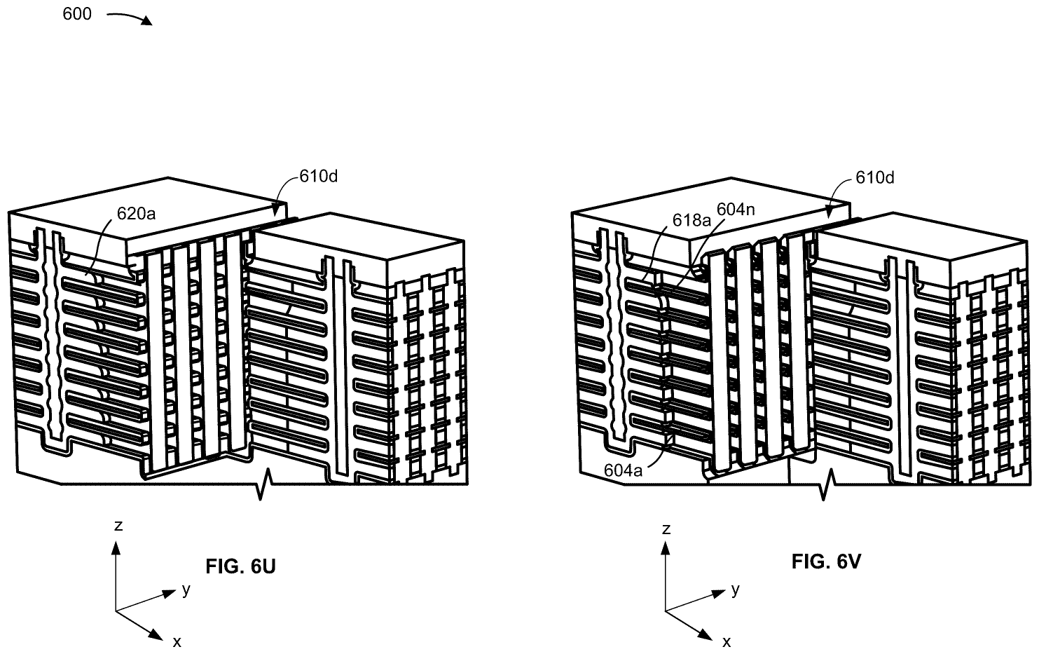

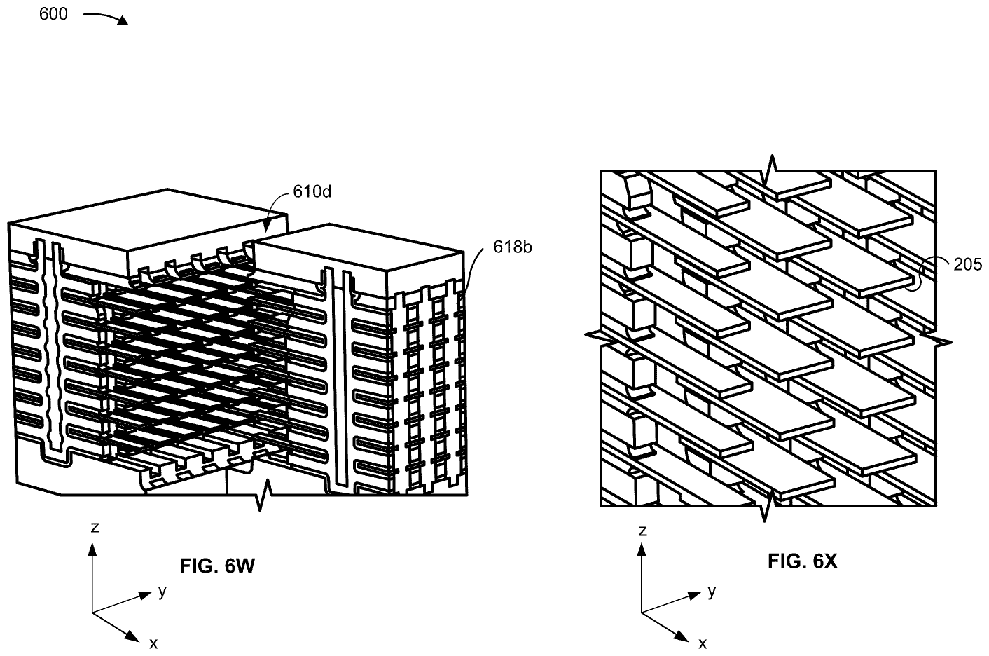

FIGS. 6A-6X through 8A-8T are diagrammatic views showing formation of the memory device 200 of FIG. 2, including stages of example processes of forming the memory device 200. In some implementations, the example processes described in connection with 6A-6X through 8A-8T may correspond to the method 500 and/or one or more blocks of the method 500. However, the processes described are an example, and other processes may be used to form the memory device 200, an integrated assembly that includes the memory device 200, and or one or more parts of the memory device 200 and/or the integrated assembly.

FIGS. 6A-6X are diagrammatic isometric views showing a process 600 that include formation of a plurality of vertically-arranged cantilever structures in a memory device (e.g., the cantilever structure(s) 205 in the memory device 200).

As illustrated in FIG. 6A, the process 600 includes forming a plurality of semiconductor material layers 602a-602n interspersed with a plurality of semiconductor material layers 604a-604n on a semiconductor substrate 606 (e.g., a silicon substrate).

The plurality of semiconductor layers 602a-602n may include a silicon germanium (SiGe) material, among other examples. In some implementations, the plurality of semiconductor layers 602a-602n is formed using an epitaxial growth deposition operation or another suitable deposition operation.

The plurality of semiconductor layers 604a-604n may include a silicon (Si) material, among other examples. In some implementations, the plurality of semiconductor layers 604a-604n is formed using an epitaxial growth deposition operation or another suitable deposition operation.

As further illustrated in FIG. 6A, the process 600 includes forming a hard mask (HM) layer 608a on the layer of the semiconductor material 604n. The HM layer 608a may include a silicon nitride (SiN) material, among other examples. In some implementations, the HM layer 608a is formed using a chemical vapor deposition (CVD) operation or another suitable deposition operation.

As further illustrated in FIG. 6A, the process 600 includes forming one or more trenches 610a. As an example, the trenches 610a, which may correspond to deep trench isolation (DTI) trenches, may be formed using a photolithography patterning operation (or another suitable patterning operation) followed by a plasma-based etching operation, a chemical etching operation, or another suitable etching operation.

As illustrated in FIG. 6B, a sacrificial layer 612a is formed in the trenches 610a. The sacrificial layer 612a may include a material that may be selectively removed (e.g., selectively etched) from materials included in the plurality of semiconductor layers 604a-604n, and/or the semiconductor substrate 606. Among other examples, the sacrificial layer 612a may include a carbon (C) material.

In some implementations, the sacrificial layer 612a is formed using a plasma-enhanced chemical vapor deposition (PECVD) operation. Furthermore, and in some implementations and after deposition, the sacrificial layer 612a may be planarized using a chemical mechanical planarization (CMP) operation or another suitable planarization operation.

Turning to FIG. 6C, the process 600 includes forming a HM layer 608b on the HM layer 608a. The HM layer 608b may include a silicon nitride (SiN) material, among other examples. In some implementations, the HM layer 608b is formed using a CVD operation or another suitable deposition operation.

As illustrated in FIG. 6C, a patterned photoresist layer 614a may be formed on and/or over the HM layer 608b. In some implementations, the patterned photoresist layer 614a is formed using a photolithography patterning operation.

After forming the patterned photoresist layer 614a, and as illustrated in FIG. 6D, the process 600 includes forming one or more trenches 610b. As an example, the one or more trenches 610b may be formed using a plasma-based etching operation, a chemical etching operation, or another suitable etching operation.

After formation of the one or more trenches 610b, the patterned photoresist layer 614a may be removed. As an example, the patterned photoresist layer 614a may be removed using an ashing operation or another suitable removal operation.

Turning to FIG. 6E, the plurality of semiconductor layers 602a-602n is removed from between the layers of the semiconductor material 604a-604n, including from between the layer of the semiconductor material 604a and the semiconductor substrate 606. As an example, and if the plurality of semiconductor layers 602a-602n includes a SiGe material, removing the plurality of semiconductor layers 602a-602n may include using a wet etchant such as tetramethylammonium hydroxide (TMAH) to exhume the plurality of semiconductor layers 602a-602n.

As illustrated in FIG. 6F, the plurality of semiconductor layers 604a-604n may be thinned. As examples, the plurality of semiconductor layers 604a-604n may be thinned using a plasma-based etching operation, a chemical etching operation, or another suitable thinning operation.

Turning to FIG. 6G, and as part of the process 600, a liner layer 616a is formed on and/or over the plurality of semiconductor layers 604a-604n. The liner layer 616a may include a silicon nitride (SiN) material, among other examples. In some implementations, the liner layer 616a is formed using a CVD operation or another suitable deposition operation.

As illustrated in FIG. 6H, the liner layer 616a may include lateral portions 616a1 on surfaces of the plurality of semiconductor layers 604a-604n (e.g., the layers 604i and 604j as illustrated in FIG. 6H). The liner layer 616a may further include vertical portions 616a2 between the plurality of semiconductor layers 604a-604n. The lateral portions 616a1 and the vertical portions 614a2 may form gaps 618 between plurality of semiconductor layers 604a-604n.

Turning to FIG. 6I, and as part of the process 600, a dielectric layer 620a (e.g., a first ITD layer) is formed on and/or over the liner layer 616a. The dielectric layer 620a may include an oxide material (e.g., silicon dioxide (SiO₂)), among other examples. In some implementations, the dielectric layer 620a fills the gaps 618. In some implementations, the dielectric layer 620a is formed using a CVD operation or another suitable deposition operation.

As illustrated in FIG. 6J, a sacrificial layer 612b is formed on and/or over portions of the liner layer 616a (e.g., portions of the liner layer 616a within the trenches 610b). The sacrificial layer 612b may include a material that may be selectively removed (e.g., selectively etched) from materials included in the plurality of semiconductor layers 604a-604n, and/or the semiconductor substrate 606. Among other examples, the sacrificial layer 612b may include a carbon (C) material.

In some implementations, the sacrificial layer 612b is formed using a PECVD operation or another suitable deposition operation. Furthermore, and in some implementations and after deposition, the sacrificial layer 612b may be planarized using a CMP operation or another suitable planarization operation.

As further illustrated in FIG. 6J, the process 600 includes forming an HM layer 608c on portions of the liner layer 616a. The HM layer 608c may include a silicon nitride (SiN) material, among other examples. In some implementations, the HM layer 608c is formed using a CVD operation or another suitable deposition operation.

Turning to FIG. 6K, the HM layer 608c is planarized. In some implementations the HM layer 608c is planarized using a CMP operation or another suitable planarization operation.

As illustrated in FIG. 6L, a patterned photoresist layer 614b may be formed on and/or over portions of the HM layer 608c. In some implementations, the patterned photoresist layer 614b is formed using a photolithography patterning operation or another suitable patterning operation.

Turning to FIG. 6M, and as illustrated, portions of the HM layer 608c (e.g., portions of the HM layer 608 not protected the patterned photoresist layer) may be removed to expose the sacrificial layer 612a. As an example, the portions of the HM layer 608c may be removed using a plasma-based etching operation, a chemical etching operation, or another suitable removal operation. After removal of the portions of the HM layer 608c, the patterned photoresist layer 614b may be removed using ashing operation or another suitable removal operation.

As illustrated in FIG. 6N, and as part of the process 600, the sacrificial layer 612a is removed. Removing the sacrificial layer 612a may include exhuming the sacrificial layer 612a using a plasma-based etching operation, a chemical etching operation, or another suitable removal operation. Furthermore, removing the sacrificial layer 612a forms one or more trenches 610c.

Turning to FIG. 6O, and as illustrated, portions of the liner layer 616 are removed. Removing the portions of the liner layer 616a may include exhuming portions of the liner layer 616a (e.g., the vertical portions 616a2) that are exposed in the one or more trenches 610c. Removing the portions of the liner layer 616a may include exhuming the portions of the liner layer 616a using a plasma-based etching operation, a chemical etching operation, or another suitable removal operation.

As illustrated in FIG. 6P, and as part of the process 600, other portions of the liner layer (e.g., the lateral portions 616a1) remain after the removal operation described in connection with FIG. 6O.

Turning to FIG. 6Q, and as part of the process 600, a dielectric layer 620b (e.g., a dielectric fill layer) is formed on and/or over remaining portions of the HM layer 608c. The dielectric layer 620b may fill the trenches 610c. Furthermore, the dielectric layer 620b may include a material that may be selectively removed (e.g., selectively etched) from materials included in the liner layer 616a, the dielectric layer 620a, and/or the semiconductor substrate 606. Among other examples, the dielectric layer 620b may include a silicon oxycarbide material (SiOC) or a silicon oxynitride (SiON) material.

As illustrated in FIG. 6R, portions of the dielectric layer 620b and/or the HM layer 608c may be removed. The portions of the dielectric layer 620b and/or the HM layer 608c may be removed using a CMP operation or another suitable planarization operation. Furthermore, and after removal of the portions of the dielectric layer 620b and/or the HM layer 608c, an HM layer 608d may be formed on and/or over remaining portions of the HM layer 608c.

Turning to FIG. 6S, a patterned photoresist layer 614c may be formed on and/or over the HM layer 608d. In some implementations, the patterned photoresist layer 614c is formed using a photolithography patterning operation.

After forming the patterned photoresist layer 614c, and as illustrated in FIG. 6T, the process 600 includes opening exposed portions of the HM layer 608d and forming one or more trenches 610d. As an example, opening the exposed portions of the HM layer 608d and forming the one or more trenches 610d may include using a plasma-based etching operation, a chemical etching operation, or another suitable etching operation. After forming the one or more trenches 610d, the process 600 may include removing the patterned photoresist layer 614c using and ashing operation or another suitable removal operation.

Turning to FIG. 6U, and as part of the process 600, portions of the dielectric layer 620a (e.g., the ITD layer) may be removed. Removing the portions of the dielectric layer 620a may include exhuming the portions of the dielectric layer 620a using a plasma-based etching operation, a chemical etching operation, or another suitable removal operation through the one or more trenches 610d.

After removing the portions of the dielectric layer 620a, and as shown in FIG. 6V, portions of the liner layer 616a may be removed. Removing the portions of the liner layer 616a may include removing the portions of the liner layer 616a using a plasma-based etching operation, a chemical etching operation, or another suitable removal operation through the one or more trenches 610d.

In some implementations, and after removing the portions of the liner layer 616a, the portions of the semiconductor layers 604a-604n are thinned further (e.g., portions of the semiconductor layers 604a-604n that are exposed by removal of the portions of the dielectric layer 620 and/or the portions of the liner layer 616a). As examples, the portions of the plurality of semiconductor layers 604a-604n may be thinned further using a plasma-based etching operation, a chemical etching operation, or another suitable thinning operation through the one or more trenches 610d.

Turning to FIG. 6W, and as part of the process 600, portions of the dielectric layer 620b (e.g., the dielectric fill layer) are selectively removed. As an example, and if the dielectric layer 620b includes a silicon oxynitride (SiON) material, selectively removing the portions of the dielectric layer 620b may include using a wet etchant such as a hydrofluoric acid fluid (HF) mixed with an and ammonium fluid (NH4F) to selectively etch the portions of the dielectric layer 620b through the one or more trenches 610d.

As illustrated in FIG. 6X, and after selectively removing the portions of the dielectric layer 620b, the cantilever structure(s) 205 are exposed.

The number and arrangement of devices shown in FIGS. 6A-6X are provided as one or more examples. In practice, there may be additional devices, fewer devices, different devices, or differently arranged devices than those shown in FIGS. 6A-6X.

FIGS. 7A-7N are diagrammatic isometric views showing a process 700 that include formation of a plurality of DL LDD regions in a cantilever structure of a memory device (e.g., the DL LDD region(s) 230 in the cantilever structure(s) 205 of the memory device 200).

As illustrated in FIG. 7A, the process 700 includes forming a liner layer 616b that seals remaining portions of the dielectric layer 620a. The liner layer 616b may include an oxide material (e.g., silicon dioxide (SiO₂)), among other examples. In some implementations, the liner layer 616b is formed using a CVD operation or another suitable deposition operation.

As further illustrated in FIG. 7B, forming the liner layer 616b that seals the remaining portions of the dielectric layer 620a may include forming the liner layer 616b on and/or over exposed surfaces of the cantilever structure(s) 205.

Turning to FIG. 7C, the process 700 includes forming a liner layer 616c on and/or over the liner layer 616b. The liner layer 616c may include a silicon nitride material (e.g., SiN) among other examples. In some implementations, the liner layer 616c is formed using a CVD operation or another suitable deposition operation.

As illustrated in FIG. 7D, and as further described in connection with FIG. 7G, portions of the liner layer 616c may be removed to form the liner structures 325a and/or 325b described in connection with FIG. 3. Furthermore, and as illustrated in FIG. 7D, the liner layer 616c may include pinched portions 702 for subsequent formation of one or more conductive structures (e.g., one or more access line(s) 115).

Turning to FIG. 7E, and as part of the process 700, a dielectric layer 620c (e.g., a second ITD layer) is formed on and/or over the liner layer 616c. The dielectric layer 620c may include an oxide material (e.g., silicon dioxide (SiO₂)), among other examples. In some implementations, the dielectric layer 620c is formed using a CVD operation or another suitable deposition operation.

After forming the dielectric layer 620c, and as illustrated in FIG. 7F, portions of the dielectric layer 620c may be recessed to expose portions of the liner layer 616c. As an example, the portions of the dielectric layer 620c may be recessed using a plasma-based etching operation, a chemical etching operation, or another suitable etching operation.

Turning to FIG. 7G, and as part of the process 700, portions of the liner layer 616c are removed. As an example, the portions of the liner layer 616c may be removed using a plasma-based etching operation, a chemical etching operation, or another suitable removal operation.

Furthermore, as shown in FIG. 7H and described in connection with FIG. 3C, removal of the portions of the liner layer 616c may form the liner structures 325a and 325b on opposite sides of the cantilever structure(s) 205. As described in connection with FIG. 3D, and across a plurality of vertically-arranged memory cells, the liner structures 325a and 325b may have substantially similar widths D3.

Turning to FIG. 71, and as part of the process 700, a conductive layer 704a may be formed on and/or over portions of the liner layer 616c, between portions of the dielectric layer 620, and around the cantilever structure(s) 205. The conductive layer 704a (e.g., a conductive layer for the access line 115 of FIGS. 1 and 2) may include a polysilicon material or a metal material, among other examples. In some implementations, the conductive layer 704a is formed using a CVD operation, a plating operation, or another suitable deposition operation.

After forming the conductive layer 704a, and as illustrated in FIG. 7J, portions of the conductive layer 704a may be recessed to form the gate structure(s) 225. As an example, the portions of the conductive layer 704a may recessed using a plasma-based etching operation, a chemical etching operation, or another suitable etching operation. Furthermore, and described in connection with FIG. 3D and across a plurality of vertically-arranged memory cells, the gate structure(s) 225 may have the width D3 (e.g., sometimes referred to as a gate length).

Turning to FIG. 7K, and as part of the process 700, a liner layer 616d may be formed on and/or over exposed portions of the liner layer 616b, between portions of the dielectric layer 620, and around the cantilever structure(s) 205. The liner layer 616d layer may include a silicon nitride (SiN) material, among other examples. In some implementations, the liner layer 616d is formed using a CVD operation or another suitable deposition operation.

Additionally, as a part of the process 700 illustrated in FIG. 7K, portions of the liner layer 616d may be recessed. As an example, the portions of the liner layer 616d may be recessed using a plasma-based etching operation, a chemical etching operation, or another suitable etching operation.

As shown in FIG. 7L, remaining portions of the liner layer 616d may correspond to the width D4 described in connection with FIG. 3A (e.g., the width D4 that defines the DL LDD region(s) 230 of FIGS. 2 and 3A).

Turning to FIG. 7M, and as part of the process 700, portions of the liner layer 616b are removed to expose ends of the cantilever structure(s) 205. As an example, the portions of the liner layer 616b may be removed using a plasma-based etching operation, a chemical etching operation, or another suitable removal operation.

The exposed ends of the cantilever structure(s) 205, as shown in FIG. 7N, may be doped using a lateral doping process such as a gas phase doping (GPD) process or a selective epitaxial growth (SEG). Doping the exposed ends of the cantilever structure(s) 205 may form one or more DL LDD regions and/or CC LDD regions within the cantilever structure(s) 205 (e.g., one or more of the DL LDD region(s) 230 and/or CC LDD region(s) 215 of FIGS. 2 and 3A).

The number and arrangement of devices shown in FIGS. 7A-7N are provided as one or more examples. In practice, there may be additional devices, fewer devices, different devices, or differently arranged devices than those shown in FIGS. 7A-7N.

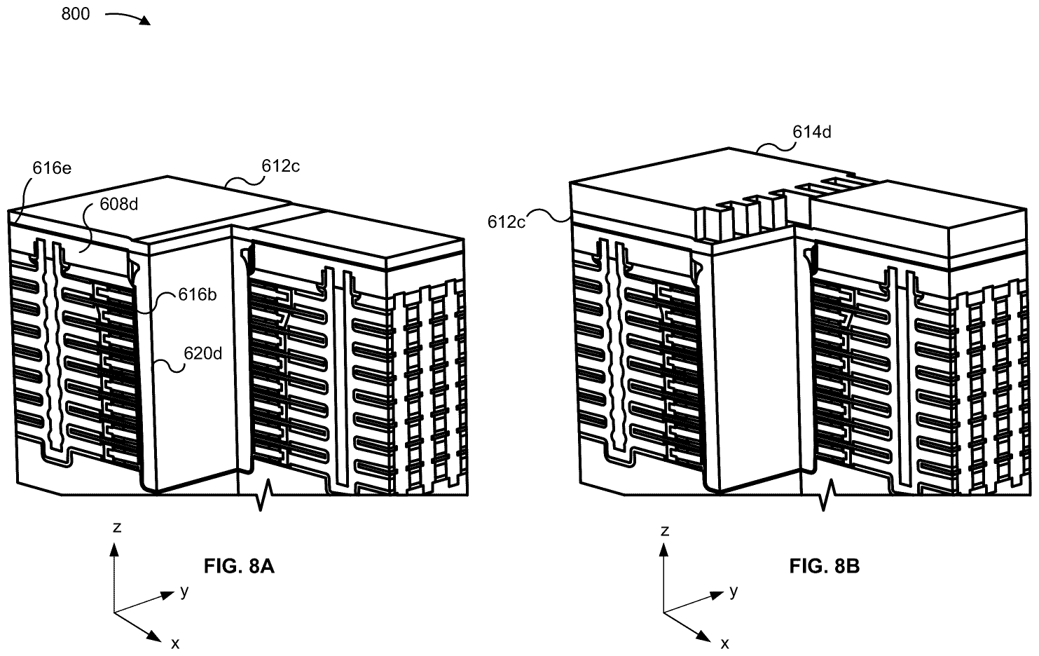

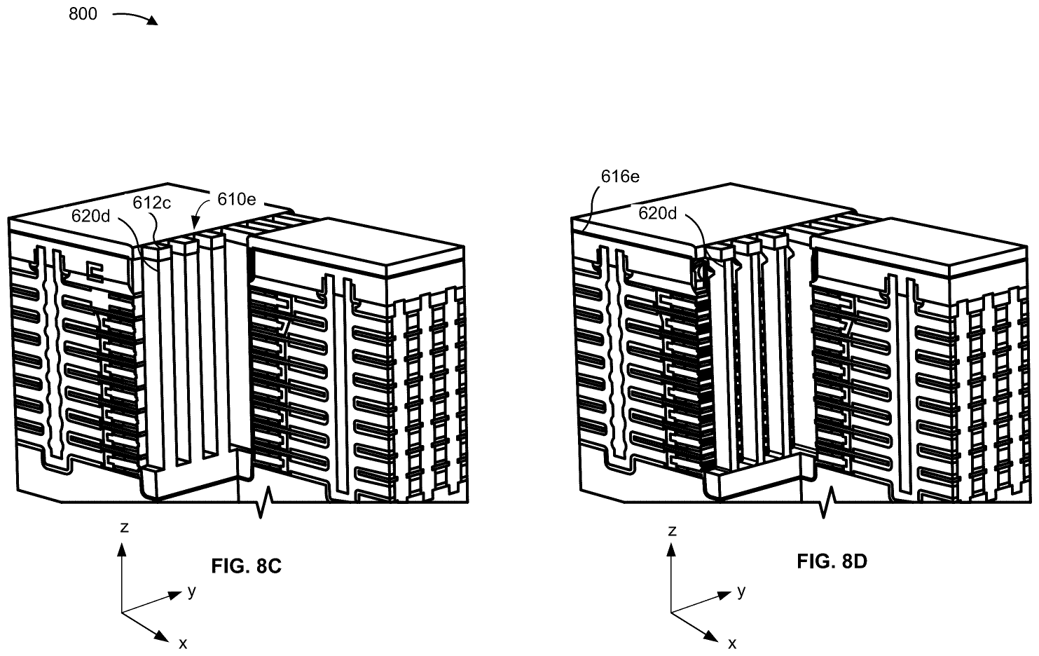

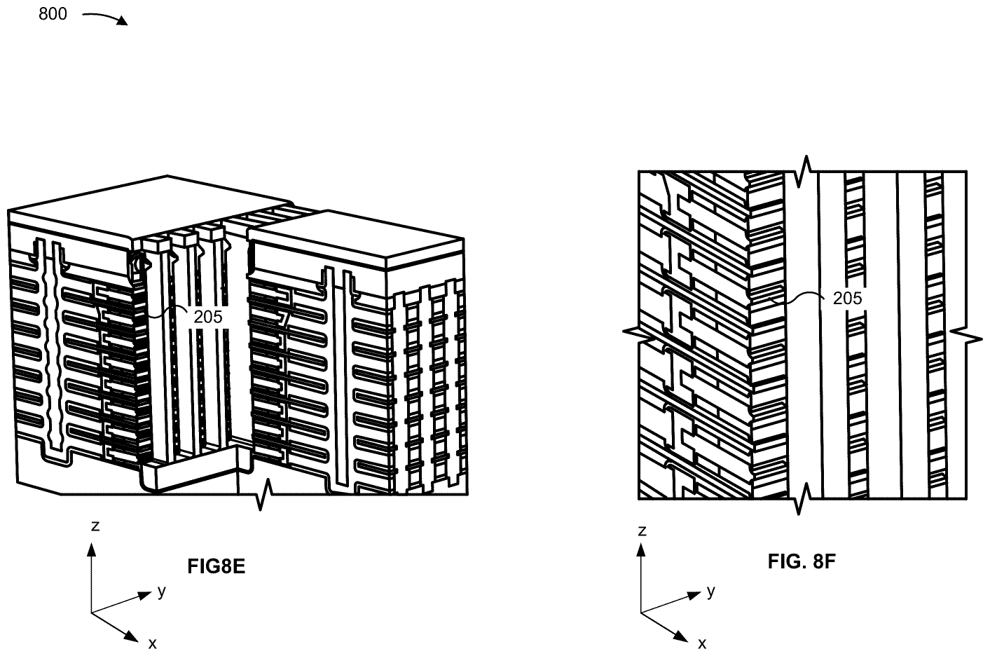

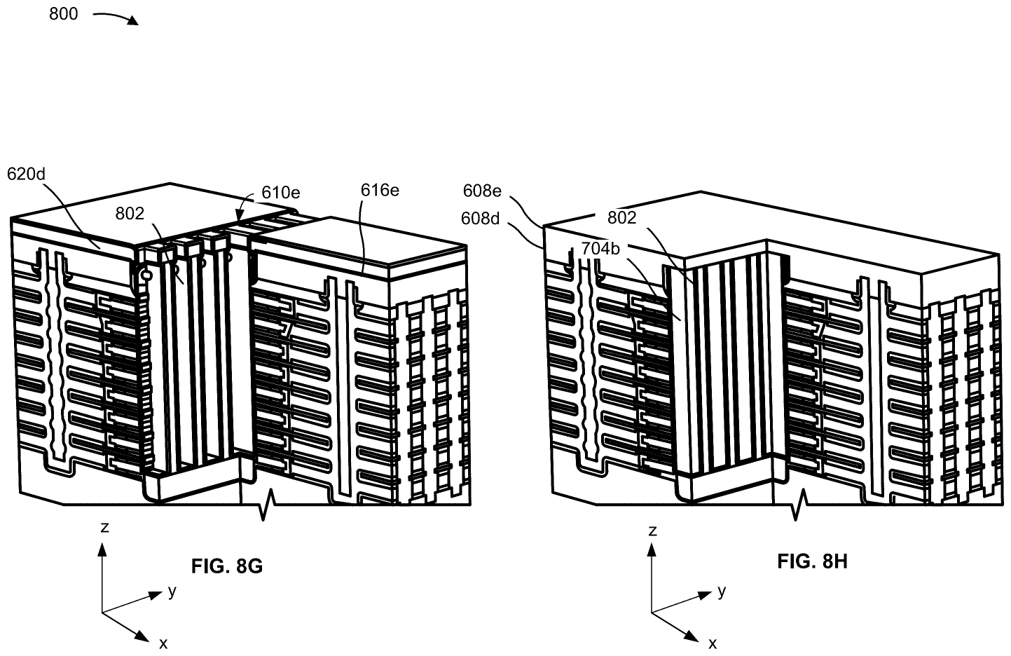

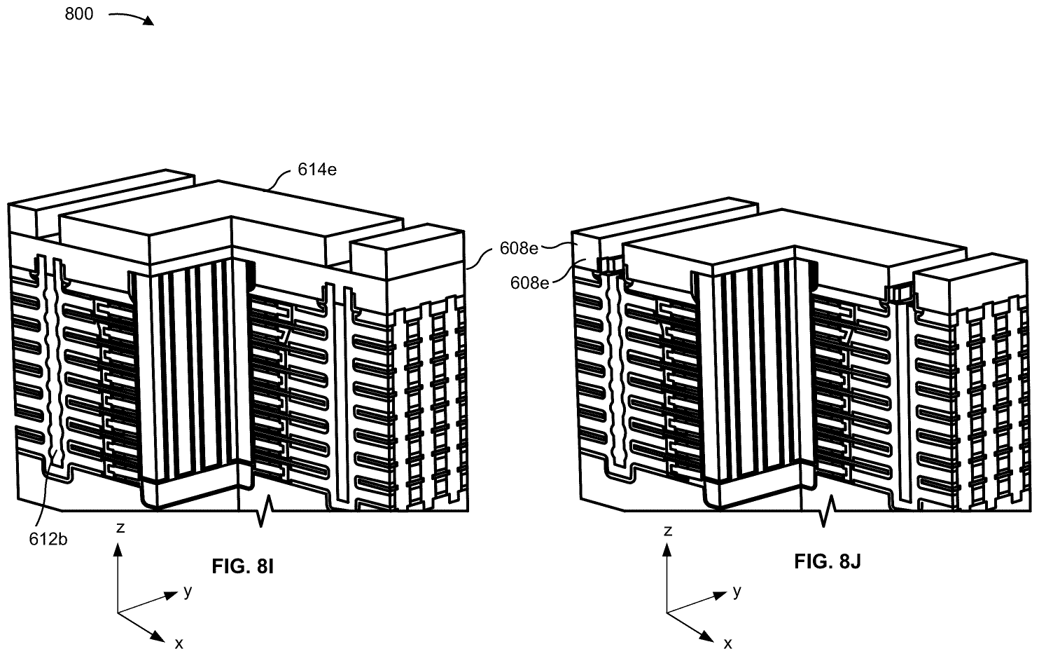

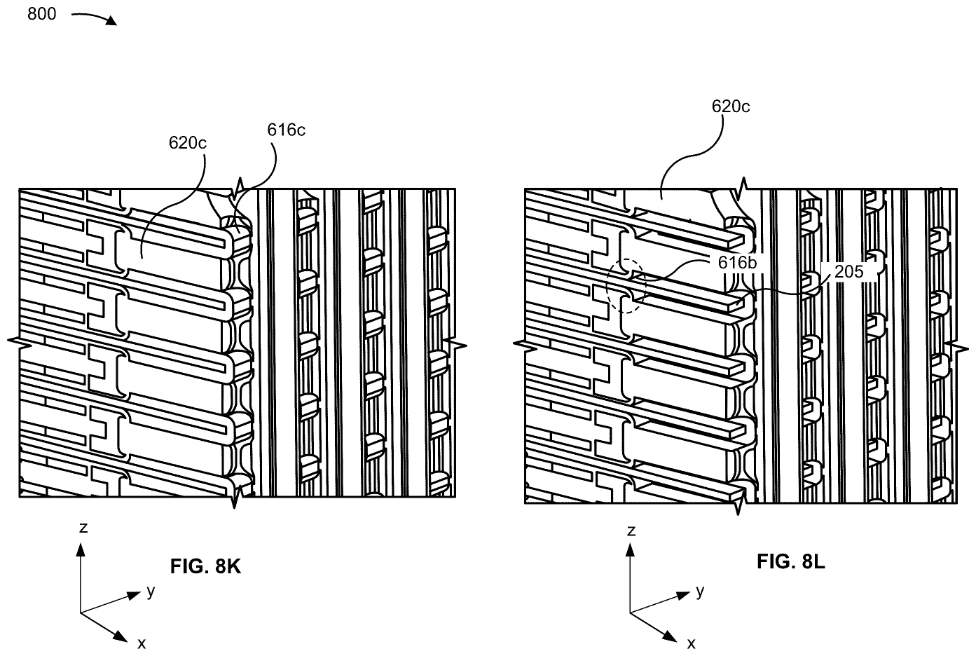

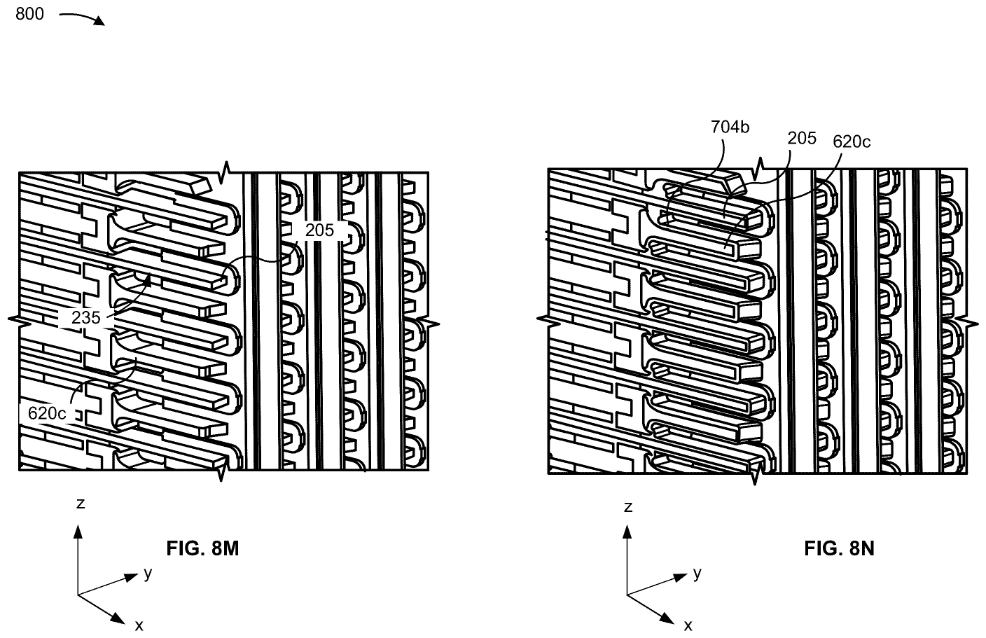

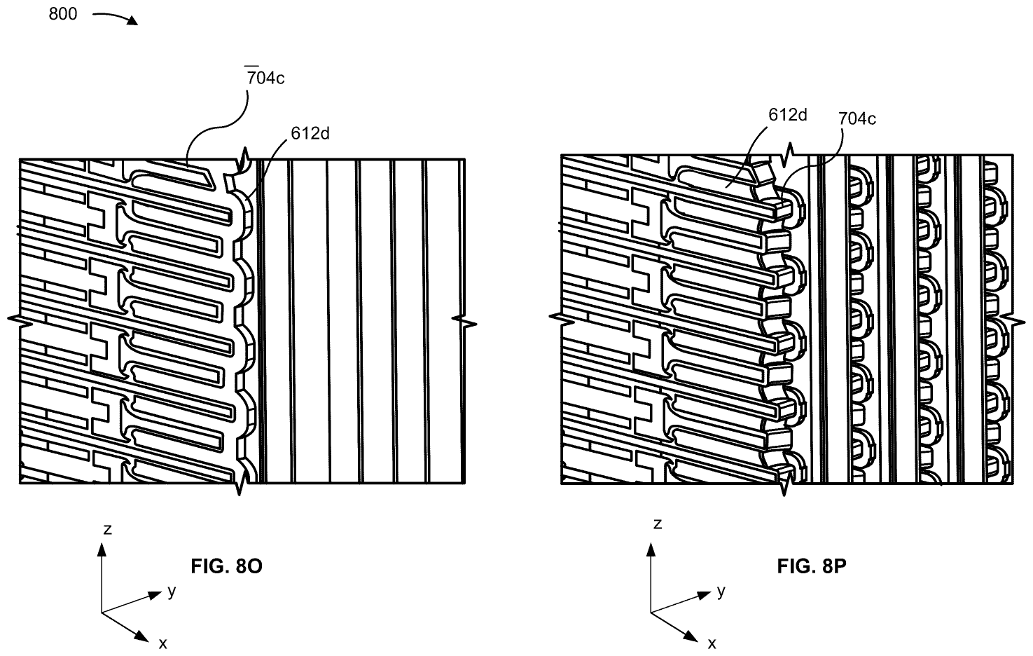

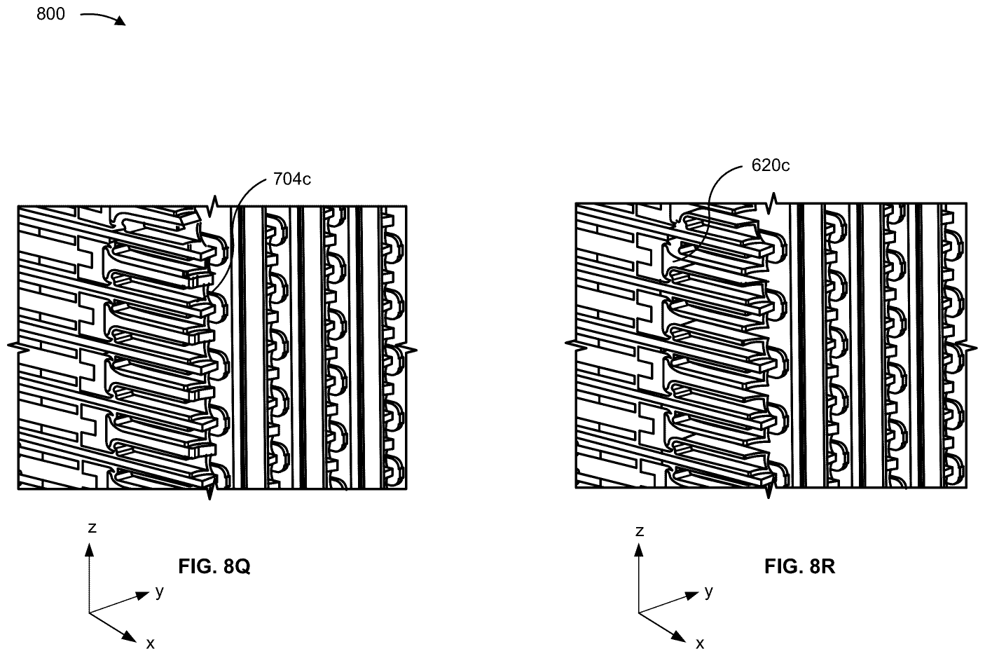

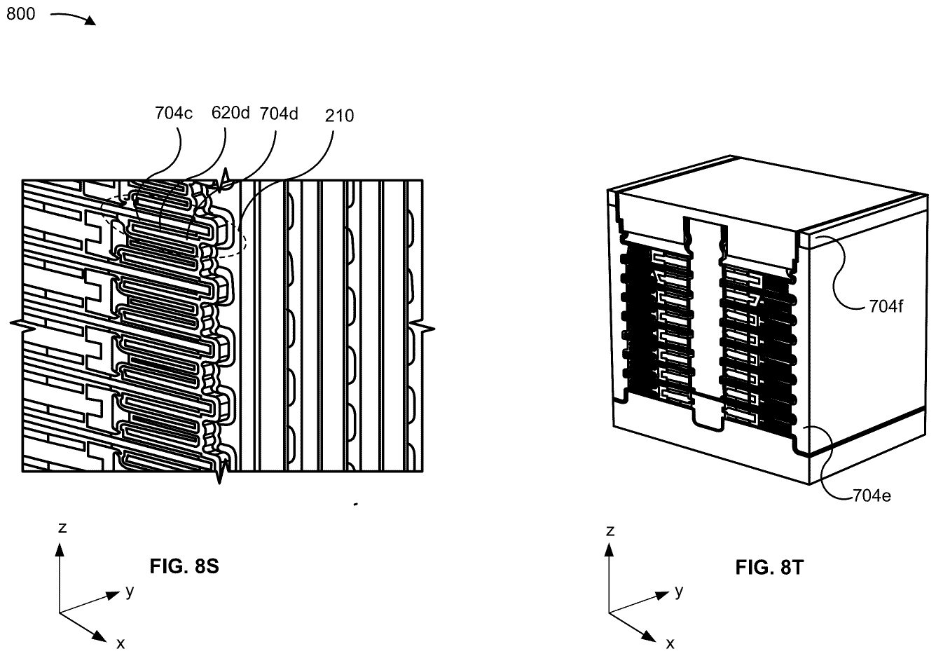

FIGS. 8A-8T are diagrammatic isometric views showing a process 800 that include formation of a plurality of vertically-arranged storage cells in a memory device (e.g., the storage cell(s) 210 in the memory device 200).

As illustrated in FIG. 8A, the process 800 includes forming a liner layer 616d on and/or over HM layer 608d, and on and/or over the liner layer 616b. The liner layer 616d may include a silicon nitride material (e.g., SiN), among other examples. In some implementations, the liner layer 616d is formed using a CVD operation or another suitable deposition operation.

As further illustrated in FIG. 8A, the process 800 includes forming a dielectric layer 620d (e.g., a dielectric fill layer) over the liner layer 616d. The dielectric layer 620d may include a spin-on dielectric (SOD) material (e.g., a spin-on divinylsiloxane-bis-benzocyclobutene material (DVS-BCB)) or a spin-on carbon (SOC) material, among other examples. Forming the dielectric layer 620d may using a spin-coating process or another suitable deposition operation.

As further in FIG. 8A, a sacrificial layer 612c may be formed on and/or over portions of the liner layer 616d and the dielectric layer 620d. Among other examples, the sacrificial layer 612c may include a carbon (C) material.

In some implementations, the sacrificial layer 612c is formed using a PECVD operation. Furthermore, and in some implementations and after deposition, the sacrificial layer 612c may be planarized using a CMP operation or another suitable planarization operation.

As illustrated in FIG. 8B, a patterned photoresist layer 614d may be formed on the sacrificial layer 612c. In some implementations, the patterned photoresist layer 614d is formed using a photolithography patterning operation.

Turning to FIG. 8C, and as part of the process 800, portions of the sacrificial layer 612c and portions of the dielectric layer 620d may be removed. Removing the portions of the sacrificial layer 612c and/or the dielectric layer 620d may include removing the portions using a plasma-based etching operation, a chemical etching operation, and/or or another suitable removal operation. Furthermore, removal of the portions of the sacrificial layer 612c and the portions of the dielectric layer 620d may form one or more trenches 610e (e.g., trenches for formation digit line contact structures)

As illustrated in FIG. 8D, portions of the dielectric layer 620d may be trimmed. Trimming the portions of the dielectric layer 620d may include using wet etching operation, a plasma-based etching operation, a chemical etching operation, or another suitable trimming operation.

Furthermore, and as illustrated in FIG. 8D, portions of the liner layers 616e and/or 616d may be exhumed. Exhuming the portions of the liner layers 616e and/or 616d may include using a plasma-based etching operation, a chemical etching operation, or another suitable exhuming operation.

Turning to FIGS. 8E and 8F, and as part of the process 800, edges of cantilever structure(s) 205 may be exposed. In some implementations, exposing the edges of the cantilever structure(s) 205 includes a pre-cleaning operation that uses a combination of solvents (e.g., acetone, isopropanol, or methanol), acids (e.g., hydrochloric acid (HCl) or sulfuric acid (H₂SO₄)), and or rinse agents (e.g., deionized water (DI)) to remove contaminants from the ends of the cantilever structure(s) 205.

Turning to FIG. 8G, and as part of the process 800, a doped semiconductor layer 802 is formed on and/or over surfaces the dielectric layer 620d including within the trenches 610e. As an example, forming the doped semiconductor layer 802 may include forming a layer of a polysilicon material using an epitaxial growth operation or another suitable deposition operation. Furthermore, and in such a case, forming the doped semiconductor layer 802 may include doping the layer of the polysilicon material with a phosphorous (P) dopant to form an (n+) poly layer.

As shown in FIG. 8H, a conductive layer 704b may be formed on and/or over the doped semiconductor layer 802. The conductive layer 704b (e.g., a conductive layer for the digit line 120 of FIGS. 1 and 2) may include a polysilicon material or a metal material, among other examples. In some implementations, the conductive layer 704b is formed using a CVD operation, a plating operation, or another suitable deposition operation.

After formation of the conductive layer 704b, portions of the conductive layer 704b, portions of the doped semiconductor layer 802, portions of the sacrificial layer 612c, and/or portions of the liner layer 616e may be removed. Removing the portions of the conductive layer 704b, portions of the doped semiconductor layer 802, portions of the sacrificial layer 612c, and/or portions of the liner layer 616e may include using a CMP process or another suitable removal operation.

Furthermore, and as part of the process 800 illustrated in FIG. 8H, an HM layer 608e may be formed over and/or on the HM layer 608d. The HM layer 608e may include a silicon nitride (SiN) material, among other examples. In some implementations, the HM layer 608e is formed using a CVD operation or another suitable deposition operation.

Turning to FIG. 8I, and as part of the process 800, a patterned photoresist layer 614e is formed on and/or over the HM layer 608e. In some implementations, the patterned photoresist layer 614e is formed using a photolithography patterning operation.

After forming the patterned photoresist layer 614e, and as illustrated in FIG. 8J, the process 800 may include opening exposed portion of the HM layer 608e and an underlying portion of HM layer 608d. Opening the exposed portion of the HM layer 608e and the underlying portion of HM layer 608d may include using a plasma-based etching operation, a chemical etching operation, or another suitable opening operation.

Further and as illustrated in FIG. 8J, the process 800 may include removing the sacrificial layer 612b. Removing the sacrificial layer 612b may include a plasma-based etching operation, a chemical etching operation, an ashing operation, or another suitable removal operation.

Turning to FIG. 8K, and as part of the process 800, portions of the dielectric layer 620c (e.g., portions of the second ITD layer) are removed to expose the liner layer 616c. Removing the portions of the dielectric layer 620c may include using a plasma-based etching operation, a chemical etching operation, or another suitable removal operation.

As illustrated in FIG. 8L, the process 800 includes recessing the liner layer 616c to expose the cantilever structure(s) 205. Recessing the liner layer 616c may include using a plasma-based etching operation, a chemical etching operation, or another suitable recessing operation. In a case where a plasma-based etching operation is used, and as shown in FIG. 8L, the plasma-based etching operation may “self-stop” on the liner layer 616b. Furthermore, in a case where the plasma-based etching operation is used, self-aligned lightly-doped drain regions (e.g., the CC LDD region(s) 215) may be formed within the cantilever structure(s) 205.

Turning to FIG. 8M, and as part of the process 800, portions of the dielectric layer 620c may be thinned. Thinning the portions of the dielectric layer 620c may include using a plasma-based etching operation, a chemical etching operation, or another suitable thinning operation.

After thinning the portions of the dielectric layer 620c, exposed portions of the cantilever structure(s) 205 may be exposed to a doping operation that penetrates into the cantilever structure(s) 205 and dopes the electrode contact region(s) 235 to increase an electrical conductivity of the electrode contact region(s) 235. As examples, doping the cantilever structure(s) 205 to dope the electrode contact region(s) 235 may include a GPD operation, a silicidation operation, or another suitable doping operation.

As shown in FIG. 8N, a conductive layer 704c may be formed on and/or over exposed portions of the cantilever structure(s) 205 and portions of the dielectric layer 620c. The conductive layer 704c (e.g., for formation of the BE layer portions 335a-335d of FIGS. 3B and 3C) may include a polysilicon material or a metal material, among other examples. In some implementations, the conductive layer 704c is formed using a CVD operation, a plating operation, or another suitable deposition operation.

Turning to FIG. 80, and as part of the process 800, a sacrificial layer 612d is formed on and/or over the conductive layer 704c. Among other examples, the sacrificial layer 612d may include a carbon (C) material. As an example, the sacrificial layer 612d may be formed using a PECVD operation or another suitable deposition operation.

As shown in FIG. 8P, and after deposition, portions of the sacrificial layer 612d may be recessed to expose portions of the conductive layer 704c. As an example, the portions of the sacrificial layer 612 d may be recessed using a plasma-based etching operation, a chemical etching operation, or another suitable recessing operation.

Turning to FIG. 8Q, and as part of the process 800, portions of the conductive layer 704c may be separated (e.g., to create separate nodes of vertically-arranged storage cell(s) 210). Separating the portions of the conductive layer 704 may include using a plasma-based etching operation, a chemical etching operation, or another suitable separating operation.

As further shown in FIG. 8Q, remaining portions of the sacrificial layer 612d may be removed. The remaining portions of the sacrificial layer 612d may be removed using a plasma-based etching operation, a chemical etching operation, an ashing operation, or another suitable removal operation.

As shown in FIG. 8R, and as part of the process 800, one or more recesses may be formed in the dielectric layer 620c. Forming the recesses in the dielectric layer 620c may include using a plasma-based etching operation, a chemical etching operation, or another suitable recessing operation.

Turning to FIG. 8S, and as part of the process 800, a dielectric layer 620d may be formed on and/or over remaining portions of the conductive layer 704c. The dielectric layer 620d (e.g., for formation of the HK layer portions 340a-340f of FIGS. 3B and 3C) may include a dielectric material such as a hafnium dioxide material (HfO₂). In some implementations, the dielectric layer 620d is formed using a CVD operation or another suitable deposition operation.

As further shown in FIG. 8S, a conductive layer 704d may be formed on and/or over the dielectric layer 620d. The conductive layer 704d (e.g., for formation of the TE layer portions 345a-345c of FIGS. 3B and 3C) may include a polysilicon material or a metal material, among other examples. In some implementations, the conductive layer 704d is formed using a CVD operation, a plating operation, or another suitable deposition operation.

As described in connection with FIGS. 2-4, and elsewhere herein, portions of the conductive layer 704c, the dielectric layer 620d, and/or the conductive layer 704d may form a plurality of the storage cell(s) 210 that are vertically-arranged.

As shown in FIG. 8T, and as part of the process 800, a conductive layer 704e may be formed on and/or over the conductive layer 704d. The conductive layer 704e may include a silicon germanium (SiGe) material, among other examples. The conductive layer 704e may be formed using a CVD operation, an epitaxial growth operation, a plating operation, or another suitable deposition operation. Furthermore, formation of the conductive layer 704e may include implanting conductive layer 704e with a dopant such as boron (B), among other examples.

In some implementations, and after formation, the conductive layer 704e is planarized. Planarizing the conductive layer 704e may include planarizing the conductive layer 704e using a CMP operation or another suitable planarization operation.

As further shown in FIG. 8T, a conductive layer 704f may be formed on and/or over a portion of the conductive layer 704e. The conductive layer 704f (e.g., a fill layer for strapping) may include a polysilicon material or a metal material, among other examples.

Forming the conductive layer 704f may include forming are recess in the conductive layer 704e using a plasma-based etching operation, a chemical etching operation, or another suitable recessing operation. Furthermore, forming the conductive layer 704f may include forming the conductive layer 704f in the recess using a CVD operation, an epitaxial growth operation, a plating operation, or another suitable deposition operation.

The number and arrangement of devices shown in FIGS. 8A-8T are provided as one or more examples. In practice, there may be additional devices, fewer devices, different devices, or differently arranged devices than those shown in FIGS. 8A-8T.

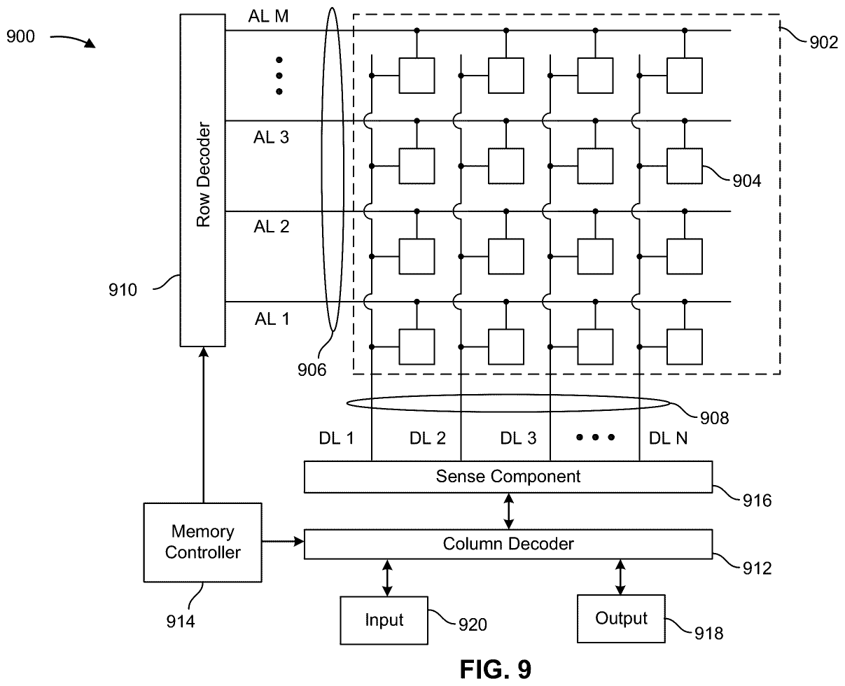

FIG. 9 is a diagrammatic view of an example memory device 900. The memory device 900 (e.g., the memory device 200 of FIG. 2) may include a memory array 902 that includes multiple memory cells 904 (e.g., multiples of the memory cell 100 of FIG. 1). A memory cell 904 is programmable or configurable into a data state of multiple data states (e.g., two or more data states). For example, a memory cell 904 may be set to a particular data state at a particular time, and the memory cell 904 may be set to another data state at another time. A data state may correspond to a value stored by the memory cell 904. The value may be a binary value, such as a binary 0 or a binary 1, or may be a fractional value, such as 0.5, 1.5, or the like. A memory cell 904 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 904 by activating or selecting the appropriate access line 906 (e.g., the access line 115 of FIG. 1, shown as access lines AL 1 through AL M) and digit line 908 (e.g., the digit line 120 of FIG. 1, shown as digit lines DL 1 through DL N). An access line 906 may also be referred to as a “row line” or a “word line,” and a digit line 908 may also be referred to a “column line” or a “bit line.” Activating or selecting an access line 906 or a digit line 908 may include applying a voltage to the respective line. An access line 906 and/or a digit line 908 may comprise, consist of, or consist essentially of a conductive material, such as a metal (e.g., copper, aluminum, gold, titanium, or tungsten) and/or a metal alloy, among other examples. In FIG. 9, each row of memory cells 904 is connected to a single access line 906, and each column of memory cells 904 is connected to a single digit line 908. By activating one access line 906 and one digit line 908 (e.g., applying a voltage to the access line 906 and digit line 908), a single memory cell 904 may be accessed at (e.g., is accessible via) the intersection of the access line 906 and the digit line 908. The intersection of the access line 906 and the digit line 908 may be called an “address” of a memory cell 904.

In some implementations, the logic storing device of a memory cell 904, such as a capacitor, may be electrically isolated from a corresponding digit line 908 by a selection component, such as a transistor. The access line 906 may be connected to and may control the selection component. For example, the selection component may be a transistor, and the access line 906 may be connected to the gate of the transistor. Activating the access line 906 results in an electrical connection or closed circuit between the capacitor of a memory cell 904 and a corresponding digit line 908. The digit line 908 may then be accessed (e.g., is accessible) to either read from or write to the memory cell 904.

A row decoder 910 and a column decoder 912 may control access to memory cells 904. For example, the row decoder 910 may receive a row address from a memory controller 914 and may activate the appropriate access line 906 based on the received row address. Similarly, the column decoder 912 may receive a column address from the memory controller 914 and may activate the appropriate digit line 908 based on the column address.

Upon accessing a memory cell 904, the memory cell 904 may be read (e.g., sensed) by a sense component 916 to determine the stored data state of the memory cell 904. For example, after accessing the memory cell 904, the capacitor of the memory cell 904 may discharge onto its corresponding digit line 908. Discharging the capacitor may be based on biasing, or applying a voltage, to the capacitor. The discharging may induce a change in the voltage of the digit line 908, which the sense component 916 may compare to a reference voltage (not shown) to determine the stored data state of the memory cell 904. For example, if the digit line 908 has a higher voltage than the reference voltage, then the sense component 916 may determine that the stored data state of the memory cell 904 corresponds to a first value, such as a binary 1. Conversely, if the digit line 908 has a lower voltage than the reference voltage, then the sense component 916 may determine that the stored data state of the memory cell 904 corresponds to a second value, such as a binary 0. The detected data state of the memory cell 904 may then be output (e.g., via the column decoder 912) to an output component 918 (e.g., a data buffer). A memory cell 904 may be written (e.g., set) by activating the appropriate access line 906 and digit line 908. The column decoder 912 may receive data, such as input from input component 920, to be written to one or more memory cells 904. A memory cell 904 may be written by applying a voltage across the capacitor of the memory cell 904.

The memory controller 914 may control the operation (e.g., read, write, re-write, refresh, and/or recovery) of the memory cells 904 via the row decoder 910, the column decoder 912, and/or the sense component 916. The memory controller 914 may generate row address signals and column address signals to activate the desired access line 906 and digit line 908. The memory controller 914 may also generate and control various voltages used during the operation of the memory array 902.

As indicated above, FIG. 9 is provided as an example. Other examples may differ from what is described with respect to FIG. 9.

In some implementations, a memory device includes a plurality of silicon cantilever structures arranged vertically; and a storage cell on an end of each of the plurality of silicon cantilever structures, each storage cell comprising: a first capacitor structure connected to a topside surface of a corresponding silicon cantilever structure and comprising: a first plurality of high-K dielectric layer portions that are vertically-arranged and interspersed with a first plurality of electrode layer portions, wherein each of the first plurality of high-K dielectric layer portions is approximately parallel to the topside surface; and a second capacitor structure connected to an underside surface of the corresponding silicon cantilever structure and comprising: a second plurality of high-K dielectric layer portions that are vertically-arranged and interspersed with a second plurality of electrode layer portions, wherein each of the second plurality of high-K dielectric layer portions is approximately parallel to the underside surface.

In some implementations, a memory device includes a plurality of storage cells that are arranged vertically; a plurality of corresponding gate all around transistors arranged adjacent to the plurality of storage cells; and a plurality of corresponding contact lightly-doped drain regions connecting the plurality of storage cells and the plurality of corresponding gate all around transistors, wherein the plurality of corresponding cell contact lightly-doped drain regions have substantially similar widths.

In some implementations, a method includes forming a plurality of vertically-arranged cantilever structures from a semiconductor material; forming a liner layer that conforms to surfaces of the plurality of vertically-arranged cantilever structures; forming an inter-tier dielectric layer over the liner layer; removing portions the inter-tier dielectric layer to expose the liner layer; removing portions of the liner layer using a single removal operation, wherein removing the portions of the liner layer exposes a plurality of cell contact regions, on surfaces of the plurality of vertically-arranged cantilever structures, that have substantially similar widths, and wherein removing the portions of the liner layer exposes surfaces of the inter-tier dielectric layer that face the plurality of cell contact regions; and doping the plurality of cell contact regions to form a plurality of cell contact lightly-doped drain regions having substantially similar widths.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are illustrated as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for case of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same clement (e.g., a+a, a+a+a, a+a+b, a+a+c, a+b+b, a+c+c, b+b, b+b+b, b+b+c, c+c, and c+c+c, or any other ordering of a, b, and c).

No clement, act, or instruction used herein should be construed as critical or essential unless explicitly described as such. Also, as used herein, the articles “a” and “an” are intended to include one or more items and may be used interchangeably with “one or more.” Furthermore, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Furthermore, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
a plurality of silicon cantilever structures arranged vertically; and
a storage cell on an end of each of the plurality of silicon cantilever structures, each storage cell comprising:
a first capacitor structure connected to a topside surface of a corresponding silicon cantilever structure and comprising:
a first plurality of high-K dielectric layer portions that are vertically-arranged and interspersed with a first plurality of electrode layer portions,
wherein each of the first plurality of high-K dielectric layer portions is approximately parallel to the topside surface; and
a second capacitor structure connected to an underside surface of the corresponding silicon cantilever structure and comprising:
a second plurality of high-K dielectric layer portions that are vertically-arranged and interspersed with a second plurality of electrode layer portions,
wherein each of the second plurality of high-K dielectric layer portions is approximately parallel to the underside surface.

2. The memory device of claim 1, further comprising:
an inter-tier dielectric layer portion between vertically adjacent storage cells,
wherein the inter-tier dielectric layer portion is between co-facing bottom electrode layer portions of the vertically adjacent storage cells.

3. The memory device of claim 1, wherein the first plurality of electrode layer portions and the second plurality of electrode layer portions each comprise:
a quantity of two bottom electrode layer portions.

4. The memory device of claim 1, wherein the first plurality of high-K dielectric layer portions essentially comprises:
a quantity of two high-K dielectric layer portions, and
wherein the second plurality of electrode layer portions essentially comprises:
a quantity of one top electrode layer portion, and
a quantity of two bottom electrode layer portions.

5. The memory device of claim 1, wherein the first plurality of high-K dielectric layer portions essentially comprises:
a quantity of three high-K dielectric layer portions, and
wherein the second plurality of electrode layer portions essentially comprises:
a quantity of two top electrode layer portions, and
a quantity of two bottom electrode layer portions.

6. The memory device of claim 1, further comprising:
a transistor gate structure for each of the plurality of silicon cantilever structures arranged vertically,
wherein each transistor gate structure is wrapped around a corresponding silicon cantilever structure.

7. The memory device of claim 1, wherein each silicon cantilever structure of the plurality of silicon cantilever structures comprises:
a dopant between the first capacitor structure and the second capacitor structure,
wherein the dopant forms a cell contact lightly-doped drain region within the silicon cantilever structure between the first capacitor structure and the second capacitor structure.

8. The memory device of claim 7, further comprising, for each silicon cantilever structure of the plurality of silicon cantilever structures:
a first liner structure above the silicon cantilever structure, and
a second liner structure below the silicon cantilever structure and below the first liner structure,
wherein the first liner structure and the second liner structure have substantially similar widths.

9. A memory device, comprising:
a plurality of storage cells that are arranged vertically;
a plurality of corresponding gate all around transistors arranged adjacent to the plurality of storage cells; and
a plurality of corresponding cell contact lightly-doped drain regions connecting the plurality of storage cells and the plurality of corresponding gate all around transistors,
wherein the plurality of corresponding cell contact lightly-doped drain regions have substantially similar widths.

10. The memory device of claim 9, wherein a width of each of the plurality of corresponding cell contact lightly-doped drain regions is included in a range of approximately 10 nanometers to approximately 100 nanometers.

11. The memory device of claim 9, wherein each of the plurality of corresponding cell contact lightly-doped drain regions is located between a corresponding liner structure that is above a cantilever structure and a corresponding liner structure that is below the cantilever structure.

12. The memory device of claim 9, wherein each of the plurality of gate all around transistors comprises a gate structure that wraps around a cantilever structure of a semiconductor material.

13. The memory device of claim 12, wherein a length of the gate structure is included in a range of approximately 10 nanometers to approximately 120 nanometers.

14. The memory device of claim 12, wherein the cantilever structure comprises:
a cell contact lightly-doped drain region of the plurality of corresponding cell contact lightly-doped drain regions having substantially similar widths.

15. A method, comprising:
forming a plurality of vertically-arranged cantilever structures from a semiconductor material;
forming a liner layer that conforms to surfaces of the plurality of vertically-arranged cantilever structures;
forming an inter-tier dielectric layer over the liner layer;
removing portions the inter-tier dielectric layer to expose the liner layer;
removing portions of the liner layer using a single removal operation,
wherein removing the portions of the liner layer exposes a plurality of cell contact regions, on surfaces of the plurality of vertically-arranged cantilever structures, that have substantially similar widths, and
wherein removing the portions of the liner layer exposes surfaces of the inter-tier dielectric layer that face the plurality of cell contact regions; and
doping the plurality of cell contact regions to form a plurality of cell contact lightly-doped drain regions having substantially similar widths.

16. The method of claim 15, wherein forming the liner layer includes:
depositing a layer of a silicon nitride material.

17. The method of claim 15, wherein the single removal operation that removes the portions of the liner layer includes:
performing an etching operation in a trench that is adjacent to the plurality of vertically-arranged cantilever structures,
wherein the etching operation includes laterally etching the liner layer.

18. The method of claim 15, wherein doping the plurality of cell contact regions includes:
performing a gas phase doping operation or a silicidation doping operation.

19. The method of claim 15, further including:
forming a storage cell on an end of each of the plurality of vertically-arranged cantilever structures.

20. The method of claim 19, wherein forming the storage cell includes:
forming a first capacitor on an exposed topside surface of a cell contact lightly-doped drain region,
wherein forming the first capacitor includes self-aligning the first capacitor to the cell contact lightly-doped drain region, and
forming a second capacitor on an exposed underside surface of the cell contact lightly-doped drain region,
wherein forming the second capacitor includes self-aligning the second capacitor to the cell contact lightly-doped drain region.

21. The method of claim 20, wherein forming the storage cell includes:
forming bottom electrode layer portions on the exposed topside surface of the cell contact lightly-doped drain region, on the exposed underside surface of the cell contact lightly-doped drain region, on an exposed surface of the inter-tier dielectric layer facing the exposed topside surface of the cell contact lightly-doped drain region, and on an exposed surface of the inter-tier dielectric layer facing the exposed underside surface of the cell contact lightly-doped drain region.

22. The method of claim 21, wherein forming the storage cell further includes:
forming a high-K dielectric layer on the bottom electrode layer portions.

23. The method of claim 22, wherein forming the high-K dielectric layer on the bottom electrode layer portions includes:
forming at least four high-K dielectric layer portions that are vertically-arranged and approximately parallel to one another.

24. The method of claim 22, wherein forming the storage cell further includes:
forming top electrode layer portions between co-facing portions of the high-K dielectric layer.

25. The method of claim 24, wherein forming the top electrode layer portions between co-facing portions of the high-K dielectric layer includes:
forming at least two top electrode layer portions that are vertically-arranged and approximately parallel to one another.
